(19) United States
(12) Patent Application Publication
(10) Pub. No.: US 2026/0082697 A1
(43) Pub. Date: Mar. 19, 2026

(54) Display Device and Display Panel

(71) Applicant: LG Display Co., Ltd., Seoul (KR)

(72) Inventors: Ahrum Sohn, Paju-si (KR); Minseong Yun, Paju-si (KR); HeeJun Kim, Paju-si (KR); Seunghee Lee, Paju-si (KR); Eunmi Cho, Paju-si (KR)

(21) Appl. No.: 19/256,732

(22) Filed: Jul. 1, 2025

(30) Foreign Application Priority Data
Sep. 13, 2024 (KR) 10-2024-0125523

(51) Int. Cl. H10D 86/40; G09G 3/00; H10K 59/88

(52) U.S. Cl. CPC H10D 86/431; G09G 3/006; H10D 86/441; G09G 2320/0247; G09G 2330/12; H10D 86/423; H10K 59/88

(57) ABSTRACT

The present disclosure provides a display panel including a display area in which subpixels are disposed, and a non-display area outside of the display area in which an image is not displayed, and a display device including the display panel and a driving circuit configured to drive the display panel. The non-display area includes a test area in which a plurality of test transistors are disposed that correspond to a plurality of transistors included in the subpixels. An operating characteristic of the test transistors is detected which is representative of an operating characteristic of the transistors included in the subpixels.

### CROSS REFERENCE TO RELATED APPLICATION

This application claims priority from Republic of Korea Patent Application No. 10-2024-0125523, filed on Sep. 13, 2024, which is hereby incorporated by reference in its entirety.

### TECHNICAL FIELD

The present disclosure relates to a display device and a display panel, and more particularly, to a display device and a display panel that include a test transistor that accurately analyzes a flicker characteristic of a driving transistor.

### BACKGROUND

In today's information society, display devices for presenting images or visual information to users are increasingly important. The need for such display devices has caused display technology to be rapidly developed, and various types of display devices, such as a liquid crystal display (LCD) device, a plasma display device, a quantum-dot light emitting display device, an organic light emitting display (e.g., OLED) device, an inorganic light emitting display device, and the like, have been developed and widely used.

Among these display devices, the organic light emitting display device has high response speed and has advantages in contrast ratio, emission efficiency, luminance, viewing angle, and the like, by using an organic light emitting diode (OLED), which is a self-emission element.

The organic light emitting display device may include organic light emitting diodes disposed in a plurality of subpixels disposed in a display panel, and can display images by light emitted from each subpixel through driving current flowing to each organic light emitting diode controlled by a corresponding driving transistor.

For example, the display device may be configured to operate at different driving frequencies based on input image data. In this implementation, when a driving frequency is changed, an operating characteristic of a transistor driving a subpixel may vary. As a result, a flicker phenomenon may occur during the process where the driving frequency is changed.

### SUMMARY

To address this issue, the inventors of the present disclosure have invented a display device and a display panel that are capable of accurately analyzing an interface characteristic of a layer that can represent an operating characteristic of a transistor with respect to the change of a driving frequency.

One or more embodiments of the present disclosure may provide a display device and a display panel that include at least one test transistor disposed in a non-display area of the display panel. The test transistor is configured to accurately reflect a capacitance-voltage characteristic of a transistor.

One or more embodiments of the present disclosure may provide a display device and a display panel that include at least one test transistor configured to reduce an influence of capacitance formed by the overlap of an active layer and a gate electrode, and are capable of accurately analyzing a flicker characteristic of a transistor by analyzing an interface characteristic of a layer adjacent to the active layer.

According to one or more example embodiments of the present disclosure, a display device can be provided that includes a display panel including a display area in which subpixels including driving transistors are disposed and a non-display area outside of the display area in which an image is not displayed, and a driving circuit driving circuit drive the display panel. In one or more aspects, the non-display area may include a test area in which a plurality of test transistors are connected in parallel for detecting a flicker characteristic of at least one of the driving transistors

According to one or more example embodiments of the present disclosure, a display panel can be provided that includes a display area in which subpixels including driving transistors are disposed, and a non-display area outside of the display area in which an image is not displayed. In one or more embodiments, the non-display area may include a test area in which a plurality of test transistors are connected in parallel for detecting a flicker characteristic of at least one of the driving transistors.

According to one or more embodiments of the present disclosure, a display device and a display panel can provide an effect or advantage of accurately analyzing an interface characteristic of a layer that can represent an operating characteristic of a transistor with respect to the change of a driving frequency.

According to one or more embodiments of the present disclosure, a display device and a display panel can provide an effect or advantage of enabling process optimization by including at least one test transistor disposed in a non-display area of the display panel and configured to accurately reflect a capacitance-voltage characteristic of a transistor.

According to one or more aspects of the present disclosure, a display device and a display panel can provide, by including at least one test transistor configured to reduce an influence of capacitance formed by the overlap of an active layer and a gate electrode, an effect or advantage of accurately analyzing a flicker characteristic of a transistor by analyzing an interface characteristic of a layer adjacent to the active layer.

In one embodiment, a display device comprises: a display panel comprising a display area in which subpixels are disposed to display an image and a non-display area outside of the display area in which the image is not displayed; and a driving circuit configured to drive the display panel, wherein the non-display area comprises test areas that include a plurality of test transistors, and a detected operation characteristic of the plurality of test transistors is representative of an operating characteristic of at least one of a plurality of transistors included in the subpixels.

In one embodiment, a display panel comprises: a display area including a plurality of subpixels; and a non-display area outside of the display area in which an image is not displayed, the non-display area comprising test areas including a plurality of test transistors, wherein an operation characteristic of the plurality of test transistors is detected that is representative of an operation characteristic of a plurality of transistors included in the subpixels.

In one embodiment, a display panel comprises: a substrate including a display area and a non-display area that is around the display area, the non-display area including a test area; a transistor in the display area of the substrate; a light emitting element in the display area, the transistor connected to the light emitting element; a plurality of test transistors in the test area of the non-display area, at least one test transistor of the plurality of test transistors on a same layer as the transistor, wherein the at least one test transistor includes: a base metal layer in the test area; a lower gate electrode overlapping the base metal layer in the test area; an active layer overlapping the lower gate electrode in the test area; an upper gate electrode overlapping the active layer in the test area; and a drain electrode contacting a first portion of the active layer in the test area and a source electrode contacting a second portion of the active layer in the test area, and wherein the lower gate electrode is non-overlapping with the drain electrode and the source electrode in the test area.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates schematically an example display device according to embodiments of the present disclosure;

FIG. 2 illustrates an example system of the display device according to embodiments of the present disclosure;

FIG. 3 illustrates an example subpixel circuit of the display device according to embodiments of the present disclosure;

FIG. 4 is an example cross-sectional view of transistors included in a subpixel in the display device according to embodiments of the present disclosure;

FIGS. 5A to 5C illustrate example states of carriers in a situation where a transistor operates according to embodiments of the present disclosure;

FIG. 6 illustrates an example capacitance-voltage (C-V) characteristic of a transistor according to frequency according to embodiments of the present disclosure;

FIG. 7 is an example plan view of the display device according to embodiments of the present disclosure;

FIG. 8 illustrates an example arrangement structure of test transistors in a test area in the display device according to embodiments of the present disclosure;

FIG. 9 is an example plan view of a test transistor disposed in a test area for detecting a C-V characteristic of a driving transistor in the display device according to embodiments of the present disclosure;

FIG. 10 is an example cross-sectional view of a first test transistor taken along line A-B in FIG. 9 according to embodiments of the present disclosure;

FIG. 11 is an example cross-sectional view of the first test transistor taken along line C-D in FIG. 9 according to embodiments of the present disclosure;

FIG. 12 is an example plan view of a second test transistor disposed in a test area for detecting a C-V characteristic of an oxide switching transistor in the display device according to embodiments of the present disclosure;

FIG. 13 is an example cross-sectional view of the second test transistor taken along line A-B in FIG. 12 according to embodiments of the present disclosure;

FIG. 14 is an example cross-sectional view of the second test transistor taken along line C-D in FIG. 12 according to embodiments of the present disclosure;

FIG. 15 is an example plan view of a third test transistor disposed in a test area for detecting a C-V characteristic of a polysilicon switching transistor in the display device according to embodiments of the present disclosure;

FIG. 16 is an example cross-sectional view of the third test transistor taken along line A-B in FIG. 15 according to embodiments of the present disclosure;

FIG. 17 is an example cross-sectional view of the third test transistor taken along line C-D in FIG. 15 according to embodiments of the present disclosure;

FIG. 18A illustrates voltages applied to the test transistor TTR and FIG. 18B is a graph showing an example C-V characteristic when a low voltage is applied to a lower gate electrode of a test transistor in the display device according to embodiments of the present disclosure; and

FIG. 19A illustrates voltages applied to the test transistor TTR and FIG. 19B is a graph showing an example C-V characteristic when a lower gate electrode of a test transistor is grounded in the display device according to embodiments of the present disclosure.

### DETAILED DESCRIPTION

Hereinafter, the present preferred embodiments of the disclosure will be described in detail with reference to the accompanying drawings. In denoting elements of the drawings by reference numerals, the same elements will be referenced by the same reference numerals although the elements are illustrated in different drawings. In the following description of the disclosure, detailed description of known functions and configurations incorporated herein may be omitted when it may make the subject matter of the disclosure rather unclear. The terms such as “including”, “having”, “containing”, “comprising of”, and “consist of” used herein are generally intended to allow other components to be added unless the terms are used with the term “only”. An element described in the singular form is intended to include a plurality of elements, and vice versa, unless the context clearly indicates otherwise.

Further, the terms “first”, “second”, “A”, “B”, “(a)”, “(b)”, or the like may be used to describe elements included in embodiments of the present disclosure. These terms are used only to distinguish one element from another; thus, related elements should not be interpreted to be limited by these terms as they are not used to define a particular order or precedence. Further, the expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers “disposed” or “interposed” between the elements or layers, unless otherwise specified. Further, the other element may be included in one or more of the two or more elements connected, combined, coupled, or contacted (to) one another.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference. In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used. In construing an element, the element is to be construed as including an error or tolerance range even where no explicit description of such an error or tolerance range is provided. Further, the term “may” fully encompasses all the meanings of the term “can.” The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element. The expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C. Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

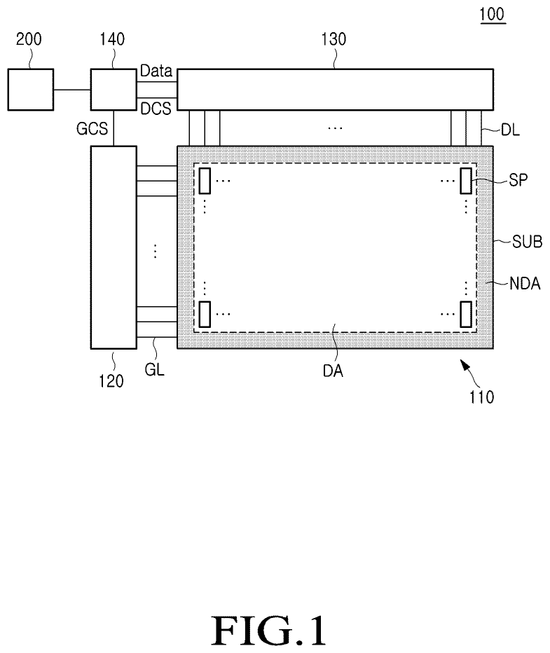

FIG. 1 illustrates schematically an example display device according to embodiments of the present disclosure.

Referring to FIG. 1, in one or more example embodiments, a display device 100 may include a display panel 110 and at least one driving circuit configured to drive the display panel 110.

The display panel 110 may include a display area DA in which an image can be displayed and a non-display area NDA in which an image is not displayed. The non-display area NDA may also be referred to as a non-active area, a bezel, or a bezel area.

The display panel 110 may include a plurality of subpixels SP for image displaying. For example, the plurality of subpixels SP may be disposed in the display area DA. In one or more aspects, at least one subpixel SP may be disposed in the non-display area NDA. The at least one subpixel SP disposed in the non-display area NDA may be referred to as a dummy subpixel.

The display panel 110 may include a plurality of signal lines for driving the plurality of subpixels SP. For example, the plurality of signal lines may include a plurality of data lines DL and a plurality of gate lines GL. The signal lines may further include other signal lines, in addition to the plurality of data lines DL and the plurality of gate lines GL, according to the structure of the subpixels SP. For example, such signal lines may include drive voltage lines, reference voltage lines, and the like.

The plurality of data lines DL and the plurality of gate lines GL may intersect each other. Each of the plurality of data lines DL may extend in a first direction. Each of the plurality of gate lines GL may extend in a second direction different from the first direction. For example, the first direction may be a column or vertical direction, and the second direction may be a row or horizontal direction. Herein, the column direction and the row direction may not represent absolute directions, but may represent relative directions. For example, the column direction may be the vertical direction and the row direction may be the horizontal direction. In another example, the column direction may be the horizontal direction and the row direction may be the vertical direction.

The at least one driving circuit may include a data driving circuit 130 configured to drive a plurality of data lines DL and a gate driving circuit 120 configured to drive a plurality of gate lines GL. The at least one driving circuit may further include a timing controller 140 configured to control the data driving circuit 130 and the gate driving circuit 120.

The data driving circuit 130 may be a circuit for driving the plurality of data lines DL and can output data signals (which may be referred to as data voltages) corresponding to image signals to the plurality of data lines DL. The gate driving circuit 120 may be a circuit for driving the plurality of gate lines GL and can generate gate signals and supply the generated gate signals to the plurality of gate lines GL. The gate signals may include at least one scan signal and at least one light emission signal.

The timing controller 140 can start to scan pixels according to respective timings set in each frame, and can control data driving at timings set for scanning corresponding one or more of the pixels. The timing controller 140 can convert image data received from an external device or system (e.g., a host system 200) to a data signal form readable by the data driving circuit 130, and then supply image data Data resulting from the converting to the data driving circuit 130.

The timing controller 140 can receive display driving control signals along with the image data from the external host system 200. For example, the display driving control signals may include a vertical sync signal, a horizontal sync signal, an input data enable signal, a clock signal, and the like.

The timing controller 140 can generate data driving control signals DCS and gate driving control signals GCS based on the display driving control signals received from the host system 200. The timing controller 140 can control the driving operation and driving timing of the data driving circuit 130 by supplying the data driving control signals DCS to the data driving circuit 130. The timing controller 140 can control the driving operation and driving timing of the gate driving circuit 120 by supplying the gate driving control signals GCS to the gate driving circuit 120.

The data driving circuit 130 may include one or more source driving integrated circuits SDIC. Each source driver integrated circuit SDIC may include a shift register, a latch circuit, a digital to analog converter, an output buffer, and the like. In one or more embodiments, each source driver integrated circuit SDIC may further include an analog-to-digital converter (ADC).

In one or more embodiments, each source driver integrated circuit SDIC may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The gate driving circuit 120 can supply a gate signal of a turn-on level voltage, a gate signal of a turn-off level voltage, or a gate signal with a turn-on level and a turn-off level according to the control of the timing controller 140. The gate driving circuit 120 can sequentially drive a plurality of gate lines GL by sequentially supplying gate signals of the turn-on level voltage to the plurality of gate lines GL.

The gate driving circuit 120 may include one or more gate driving integrated circuits GDIC.

In one or more embodiments, the gate driving circuit 120 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. However, aspects of the present disclosure are not limited thereto. In one or more aspects, the gate driving circuit 120 included in the display device 100 may be disposed in the non-display area NDA of the display panel 110 by a gate-in-panel (GIP) technique. The gate driving circuit 120 may be disposed on a substrate or connected to the substrate. In an example where the gate driving circuit 120 is implemented in the display device 100 by the gate-in-panel (GIP) technique, the gate driving circuit 120 may be disposed in the non-display area NDA of the substrate. In one or more aspects, the gate driving circuit 120 may be connected to the substrate SUB when the gate driving circuit 130 is implemented by the chip-on-glass (COG) technique, the chip-on-film (COF) technique, or the like.

In one or more embodiments, at least one of the data driving circuit 130 and the gate driving circuit 120 may be disposed in the display area DA. For example, at least one of the data driving circuit 130 and the gate driving circuit 120 may be disposed not to overlap (e.g., non-overlapping) with subpixels SP, or be disposed to overlap with one or more, or all, of the subpixels SP.

The data driving circuit 130 may be located in, and/or electrically connected to, but not limited to, only one side or edge (e.g., an upper portion or a lower portion) of the display panel 110. In one or more aspects, the data driving circuit 130 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 120 may be located in, and/or electrically connected to, but not limited to, only one side or edge (e.g., a left portion or a right portion) of the display panel 110. In one or more aspects, the gate driving circuit 120 may be disposed in, and/or electrically connected to, but not limited to, two sides or edges (e.g., a left portion and a right portion) of the display panel 110 or at least two of four sides or edges (e.g., the left portion, the right portion, an upper portion, and a lower portion) of the display panel 110 according to driving schemes, panel design schemes, or the like.

The timing controller 140 may be implemented in a separate component from the data driving circuit 130, or integrated with the data driving circuit 130, so that the timing controller 140 and the data driving circuit 130 can be implemented in a single integrated circuit. The timing controller 140 may be a controller used in the typical display technology or a control apparatus/device capable of additionally performing other control functionalities in addition to the typical function of the timing controller. In one or more embodiments, the timing controller 140 may be one or more other control circuits different from the timing controller, or a circuit or component in the control apparatus/device. The timing controller 140 may be implemented with various circuits or electronic components such as an integrated circuit (IC), a field programmable gate array (FPGA), an application specific integrated circuit (ASIC), a processor, and/or the like.

The timing controller 140 may be mounted on a printed circuit board, a flexible printed circuit, or the like, and may be electrically connected to the data driving circuit 130 and the gate driving circuit 120 through the printed circuit board, the flexible printed circuit, and/or the like. The timing controller 140 can transmit signals to, and receive signals from, the data driving circuit 130 via one or more predetermined interfaces. For example, such interfaces may include a low voltage differential signaling (LVDS) interface, an embedded clock point-point interface (EPI), a serial peripheral interface (SPI), and the like.

In one or more embodiments, the display device 100 may be a liquid crystal display device, a self-emission display device in which light is emitted from the display panel 110 itself, or the like. In an example where the display device 100 is a self-emission display device, each of the plurality of subpixels SP included in the display device 100 may include a light emitting element such as an organic light emitting diode, an inorganic light emitting diode, a quantum dot light emitting diode, a micro light emitting diode, a mini light emitting diode, or the like. In one or more embodiments, the display device 100 may be an organic light emitting display device in which the light emitting element is implemented using an organic light emitting diode (OLED). In one or more aspects, the display device 100 may be an inorganic light emitting display device in which the light emitting element is implemented using an inorganic material-based light emitting diode. In one or more aspects, the display device 100 may be a quantum dot display device in which the light emitting element is implemented using quantum dots, which are self-emission semiconductor crystals.

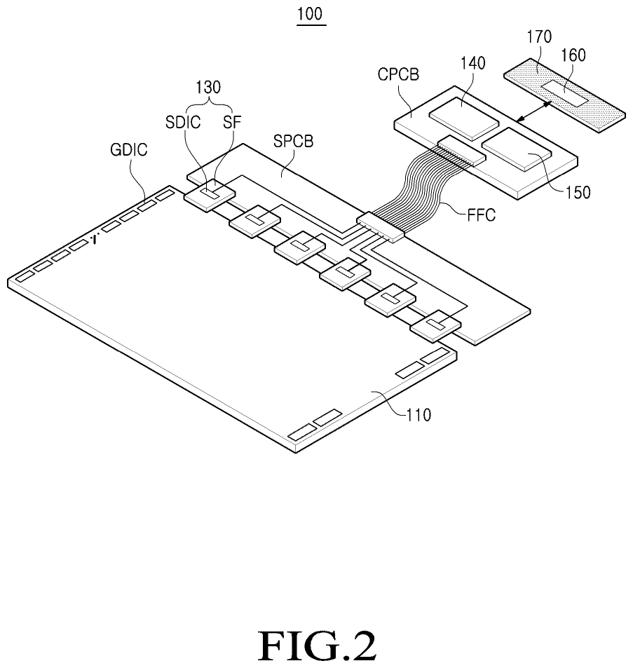

FIG. 2 illustrates an example system of the display device 100 according to embodiments of the present disclosure.

Referring to FIG. 2, in one or more example embodiments, the data driving circuit 130 and the gate driving circuit 120 included in the display device 100 may be implemented by the chip-on-film (COF) technique and the gate-in-panel (GIP) technique, respectively, among various techniques such as the tape-automated-bonding (TAB) technique, the chip-on-glass (COG) technique, the COF technique, and the like.

In an example where the gate driving circuit 120 is implemented by the GIP technique, a plurality of gate driving integrated circuits GDIC included in the gate driving circuit 120 may be disposed directly in the non-display area NDA of the display panel 110. In this example, the gate driving integrated circuits GDIC can receive various types of signals (e.g., clock signals, gate high signals, gate low signals, and the like) needed for generating scan signals through gate driving-related signal lines disposed in the non-display area NDA.

In one or more embodiments, one or more source driving integrated circuits SDIC included in the data driving circuit 130 may be mounted on one or more respective source films SF, and one side of each source film SF may be electrically connected to the display panel 110. In one or more aspects, lines for electrically connecting the one or more source driving integrated circuits SDIC and the display panel 110 may be respectively disposed in upper portions of the one or more source films SF.

The display device 100 may include at least one source printed circuit board SPCB for circuital connections between the one or more source driving integrated circuits SDIC and other units or devices, and a control printed circuit board CPCB for mounting control components and several types of electrical units or devices.

In one or more embodiments, one side of a source film SF on which a source driving integrated circuit SDIC is mounted may be connected to the at least one source printed circuit board SPCB. For example, one side of the source film SF on which the source driving integrated circuit SDIC is mounted may be electrically connected to the at least one source printed circuit board SPCB, and the other side thereof may be electrically connected to the display panel 110.

The timing controller 140 and the power management circuit 150 may be mounted on the control printed circuit board CPCB. The timing controller 140 can control operations of the data driving circuit 130 and the gate driving circuit 120. The power management circuit 150 can supply various levels of voltages or currents to the display panel 110, the gate driving circuit 120, the data driving circuit 130, and the like, or control various levels of voltages or currents to be supplied.

The at least one source printed circuit board SPCB and the control printed circuit board CPCB may be electrically connected to each other through at least one connector, such as a flexible printed circuit FPC, a flexible flat cable FFC, and/or the like. In one or more aspects, the at least one source printed circuit board SPCB and the control printed circuit board CPCB may be integrated into one printed circuit board.

The display device 100 may further include a set board 170 electrically connected to the control printed circuit board CPCB. The set board 170 may be referred to as a power board. A main power management circuit 160 configured to manage the entire power of the display device 100 may be mounted on the set board 230. The main power management circuit 160 may interoperate with the power management circuit 150.

In the example where the display device 100 includes the power management circuit 150, the set board 170, the control printed circuit board CPCB, and the like as described above, one or more driving voltages generated by the set board 170 may be transmitted to the power management circuit 150 of the control printed circuit board CPCB. The power management circuit 150 may transmit one or more driving voltages needed for display driving or characteristic value sensing to the source printed circuit board SPCB through the flexible printed circuit FPC or the flexible flat cable FFC. One or more driving voltages transmitted to the source driver integrated circuit SPCB may be supplied to the display panel 110 through one or more source driver integrated circuits SDIC, and used to enable one or more specific subpixels SP to emit light or sense one or more subpixels SP.

In one or more embodiments, each subpixel SP included in the display panel 110 of the display device 100 may include circuit elements, such as a light emitting element (e.g., an organic light emitting diode OLED), a driving transistor for driving the light emitting element, and the like.

Types of circuit elements and the number of the circuit elements included in each subpixel SP may be different depending on types of the panel (e.g., an LCD panel, an OLED panel, etc.), provided functions, design schemes/features, or the like.

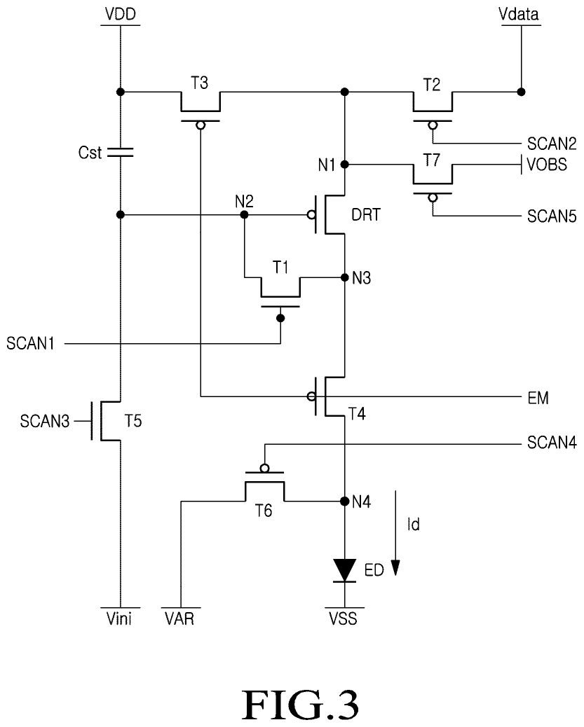

FIG. 3 illustrates an example subpixel circuit of the display device 100 according to embodiments of the present disclosure.

Referring to FIG. 3, in one or more example embodiments, each, or one or more, of a plurality of subpixels SP included in the touch display device 100 may include first to seventh switching transistors (T1 to T7), a driving transistor DRT, a storage capacitor Cst, and a light emitting element ED.

In one or more embodiments, the light emitting element ED may be a self-emission element, such as an organic light-emitting diode (OLED), an inorganic light emitting diode, a quantum dot light emitting diode, a micro light emitting diode, a mini light emitting diode, or the like.

In one or more embodiments, the second to fourth switching transistors (T2 to T4), the sixth switching transistor T6, and the seventh switching transistor T7 may be P-type transistors. In one or more aspects, the first switching transistor T1 and the fifth switching transistor T5 may be N-type transistors.

The driver transistor DRT may be either a P-type or an N-type transistor. It should be noted that FIG. 3 illustrates a P-type of driving transistor DRT as an example, but aspects of the present disclosure are not limited thereto.

P-type transistors are relatively more reliable than N-type transistors. In the example where the P-type of driving transistor DRT is used, since a high driving voltage VDD can be applied fixed or constantly to its source electrode when the light emitting element ED is driven to emit light, the application of the P-type of driving transistor DRT can provide advantages of preventing or reducing current flowing to the light emitting element ED from fluctuating due to the capacitor Cst. Therefore, the driving transistor DRT can provide stably current for driving the light emitting element ED.

When the P-type of driving transistor DRT operates in a saturation region in a configuration where the P-type of driving transistor DRT is connected to an anode electrode of the light emitting element ED, the P-type of driving transistor DRT can provide a constant current to the light emitting element ED regardless of a change in a threshold voltage, resulting in relatively high reliability.

In the subpixel circuit based on the configurations discussed above, the N-type transistors may be oxide transistors formed using an oxide semiconductor, for example, transistors having a channel formed from an oxide semiconductor such as indium, gallium, zinc oxide, indium gallium zinc oxide (IGZO), indium gallium zinc tin oxide (IGZTO), or the like). The P-type transistor may be silicon transistors formed using a semiconductor such as silicon, for example, transistors having a polysilicon channel formed by a low-temperature process referred to as LTPS or low-temperature polysilicon.

The oxide transistors may have the characteristic of relatively lower leakage current than silicon transistors.

Taking account of these characteristics, a driving transistors DRT or at least part of switching transistors included in subpixels SP may be oxide transistors.

For example, the driving transistor DRT, the first switching transistor T1 connected to the gate electrode of the driving transistor DRT, and the fifth switching transistor T5 may be oxide transistors.

For example, the remaining switching transistors (T2, T3, T4, T6 and T7) may be low-temperature polysilicon transistors.

According to these examples, each, or one or more, of the subpixel SP included in the display device 100 may include the driving transistor DRT and a first group of switching transistors (T1 and T5), which are oxide transistors, and a second group of switching transistors (T2, T3, T4, T6, and T7), which are low-temperature polysilicon transistors.

As the driving transistor DRT implemented as an oxide transistor is used, the display device 100 can provide an effect or advantage of preventing or reducing leakage current from flowing to the gate electrode of the driving transistor DRT, and thereby, reducing or eliminating undesirable image artifacts such as flicker and the like.

In one or more embodiments, to improve a current characteristic in a turn-on state and provide high reliability, the driving transistor DRT may have a dual gate structure including an upper gate electrode and a lower gate electrode.

It should be noted that the source electrode and the drain electrode of the switching transistors may be referred to as the drain electrode and the source electrode, respectively, depending on an input voltage.

A first scan signal SCAN1 may be applied to the gate electrode of the first switching transistor T1. A second electrode (e.g., the drain electrode) of the first switching transistor T1 may be connected to the gate electrode N2 of the driving transistor DRT. A first electrode (e.g., the source electrode) of the first switching transistor T1 may be connected to a second electrode (e.g., the drain electrode) N3 of the driving transistor DRT.

The first switching transistor T1 may be turned on by the first scan signal SCAN1 and form a current path between the gate electrode N2 and the second electrode N3 of the driving transistor DRT by the storage capacitor Cst with one electrode to which a high driving voltage VDD is fixedly applied.

The first switching transistor T1 may be an N-type MOS transistor formed as an oxide transistor. Since the N-type MOS transistor uses, as carriers, electrons rather than holes, the N-type MOS transistor can provide carrier mobility faster than the P-type MOS transistor, and thus provide a faster switching speed.

In one or more embodiments, the first switching transistor T1 may have a multi-gate structure to reduce or eliminate leakage current due to charge injection while the display device 100 is driven to display an image. For example, a dual-gate structure in which two gate electrodes are connected as one may be employed.

A second scan signal SCAN2 may be applied to the gate electrode of the second switching transistor T2. A data voltage Vdata may be supplied to a first electrode (e.g., the source electrode) of the second switching transistor T2. A second electrode (e.g., the drain electrode) of the second switching transistor T2 may be connected to a first electrode (e.g., the source electrode) N1 of the driving transistor DRT. The second switching transistor T2 may be turned on by the second scan signal SCAN2 and allow the data voltage Vdata to be passed to the first electrode (e.g., the source electrode) N1 of the driving transistor DRT.

In a state where the first switching transistor T1 is turned on, as the data voltage Vdata is supplied to the first electrode (e.g., the source electrode) N1 of the driving transistor DRT through the second switching transistor T2, a difference (Vdata-Vth) between the data voltage Vdata and a threshold voltage Vth of the driving transistor DRT can be sampled and supplied to the gate electrode N2 of the driving transistor DRT. According to this operation, the first switching transistor T1 may be referred to as a sampling transistor, and the first scan signal SCAN1 may be referred to as a sampling scan signal.

An emission signal EM may be applied to the gate electrode of the third switching transistor T3. The high driving voltage VDD may be applied to a first electrode (e.g., the source electrode) of the third switching transistor T3. A second electrode (e.g., the drain electrode) of the third switching transistor T3 may be connected to the first electrode (e.g., the source electrode) N1 of the driving transistor DRT. The third switching transistor T3 may be turned on by the emission signal EM and allow the high driving voltage VDD to be passed to the first electrode (e.g., the source electrode) N1 of the driving transistor DRT.

The emission signal EM may be applied to the gate electrode of the fourth switching transistor T4. A first electrode (e.g., the source electrode) of the fourth switching transistor T4 may be connected to the second electrode (e.g., the drain electrode) N3 of the driving transistor DRT. A second electrode (e.g., the drain electrode) of the fourth switching transistor T4 may be connected to the anode electrode N4 of the light emitting element ED. The fourth switching transistor T4 may be turned on by the emission signal EM and allow a driving current Id to flow to the anode electrode N4 of the light emitting element ED.

A third scan signal SCAN3 may be applied to the gate electrode of the fifth switching transistor T5. For example, the third scan signal SCAN3 may be a signal having a phase different from a first scan signal SCAN1 applied to another subpixel SP at a different location from the subpixel SP to which the third scan signal SCAN3 is applied. For example, when the first scan signal SCAN1 is applied to an nth gate line, the third scan signal SCAN3 may be supplied using a first scan signal SCAN1 applied to an (n-1)th gate line. For example, the third scan signal SCAN3 may be supplied by using the first scan signal SCAN1 delivered through a different gate line GL according to a phase at which the display panel 110 is driven.

An initialization voltage Vini may be applied to a second electrode (e.g., the drain electrode) of the fifth switching transistor T5. A first electrode (e.g., the source electrode) of the fifth switching transistor T5 may be connected to the gate electrode N2 of the driving transistor DRT and the storage capacitor Cst. The fifth switching transistor T5 may be turned on by the third scan signal SCAN3 and allow the initialization voltage Vini to be applied to the gate electrode N2 of the driving transistor DRT. According to this operation, the fifth switching transistor T5 may be referred to as an initialization transistor, and the third scan signal SCAN3 may be referred to as an initialization scan signal.

In one or more embodiments, the fifth switching transistor T5 may have a multi-gate structure to reduce or eliminate leakage current due to charge injection while the display device 100 is driven to display an image. For example, a dual-gate structure in which two gate electrodes are connected as one may be employed.

A fourth scan signal SCAN4 may be applied to the gate electrode of the sixth switching transistor T6. A reset voltage VAR may be applied to a first electrode (e.g., the source electrode) of the sixth switching transistor T6. A second electrode (e.g., the drain electrode) of the sixth switching transistor T6 may be connected to the anode electrode N4 of the light emitting element ED. The sixth switching transistor T6 may be turned on by the fourth scan signal SCAN4 and allow the reset voltage VAR to be passed to the anode electrode N4 of the light emitting element ED.

A fifth scan signal SCAN5 may be applied to the gate electrode of the seventh switching transistor T7. A bias voltage VOBS may be applied to a first electrode (e.g., the source electrode) of the seventh switching transistor T7. A second electrode (e.g., the drain electrode) of the seventh switching transistor T7 may be connected to the first electrode (e.g., the source electrode) N1 of the driving transistor DRT.

For example, the fifth scan signal SCAN5 may be a signal having a phase different from a third scan signal SCAN3 applied to another subpixel SP at a different location from the subpixel SP to which the fifth scan signal SCAN5 is applied. For example, when the third scan signal SCAN3 is applied to an nth gate line, the fifth scan signal SCAN5 may be supplied using a third scan signal SCAN3 applied to an (n-1)th gate line. For example, the fifth scan signal SCAN5 may be supplied by using the third scan signal SCAN3 delivered through a different gate line GL according to a phase at which the display panel 110 is driven.

Since the fifth scan signal SCAN5 is a signal for applying the bias voltage VOBS to the driving transistor DRT, the fifth scan signal SCAN5 may be desirable to be different from the second scan signal SCAN2 for applying a data voltage Vdata.

The gate electrode N2 of the driving transistor DRT may be connected to the second electrode (e.g., the drain electrode) of the first switching transistor T1. The first electrode (e.g., the source electrode) N1 of the driving transistor DRT may be connected to the second electrode (e.g., the drain electrode) of the second switching transistor T2. The second electrode (e.g., the drain electrode, N3) of the driving transistor DRT may be connected to the first electrode (e.g., the source electrode) of the first switching transistor T1.

The driving transistor DRT may be turned on by a difference in voltage between the gate electrode N2 and the first electrode (e.g., the source electrode) N1, and can supply a driving current Id to the light emitting element ED.

The first electrode (e.g., the source electrode) and the second electrode (e.g., the drain electrode) of the first switching transistor T1 may be connected to the second electrode (e.g., the drain electrode) N3 and the gate electrode N2 of the driving transistor DRT, respectively. In a state where the first switching transistor T1 is turned on, the operations of sampling, and compensating for, a threshold voltage of the driving transistor DRT may be performed by a data voltage Vdata applied to the first electrode (e.g., the source electrode) N1 of the driving transistor DRT.

One side or electrode of the storage capacitor Cst may be applied with the high driving voltage VDD, and the other side or electrode thereof may be connected to the gate electrode N2 of the driving transistor DRT. The storage capacitor Cst can store a voltage at the gate electrode N2 of the driving transistor DRT.

The anode electrode N4 of the light emitting element ED may be connected to the second electrode (e.g., the drain electrode) of the fourth switching transistor T4 and the second electrode (e.g., the drain electrode) of the sixth switching transistor T6. A base voltage VSS with a low level of voltage may be applied to a cathode electrode of the light emitting element ED.

The light emitting element ED can emit light at a predetermined luminescence by a driving current Id supplied by the driving transistor DRT.

In one or more embodiments, the initialization voltage Vini may be supplied to stabilize a change in capacitance formed through the gate electrode N2 of the driving transistor DRT, and the reset voltage VAR may be supplied to reset the anode electrode N4 of the light emitting element ED.

In a state where the fourth switching transistor T4, which is located between the anode electrode N4 of the light emitting element ED and the second electrode (e.g., the drain electrode) N3 of the driving transistor DRT and controlled by the emission signal EM, is turned off, the anode electrode N4 of the light emitting element ED can be reset when the reset voltage VAR is supplied to the anode electrode N4 of the light emitting element ED.

The sixth switching transistor T6 for supplying the reset voltage VAR may be connected to the anode electrode N4 of the light emitting element ED.

To enable the driving operation of the driving transistor DRT and the resetting operation of the anode electrode N4 of the light emitting element ED to be performed separately, the third scan signal SCAN3 for driving and/or initializing the driving transistor DRT and the fourth scan signal SCAN4 for controlling the supply of the reset voltage VAR to the anode electrode N4 of the light emitting element ED may be supplied as signals different from each other.

In one or more embodiments, when the switching transistors T5 and T6) for supplying the initialization voltage Vini and the reset voltage VAR are turned on, the fourth switching transistor T4 interconnecting the drain electrode N3 of the driving transistor DRT and the anode electrode N4 of the light emitting element ED may be turned off, and thereby, a driving current Id from the driving transistor DRT can be prevented or redecued from flowing to the anode electrode N4 of the light emitting element ED, and the anode electrode N4 can be prevented or reduced from being affected by any voltage other than the reset voltage VAR.

As in the illustration of FIG. 3, the subpixel circuit including eight transistors (DRT, T1, T2, T3, T4, T5, T6, and T7) and one storage capacitor Cst may be referred to as an 8T1C structure.

Herein, in one or more example embodiments, among subpixel circuits of various structures, the 8T1C structure may be applied to each, one or more, of subpixels SP included in the display device 100 as shown in FIG. 1 as an example, but the structure and number of transistors and capacitors included in the subpixel(s) SP may be changed according to design requirements. In one or more aspects, each of a plurality of subpixels SP may have the same structure, or one or more of the plurality of subpixels SP may have a structure different from the remaining subpixels SP.

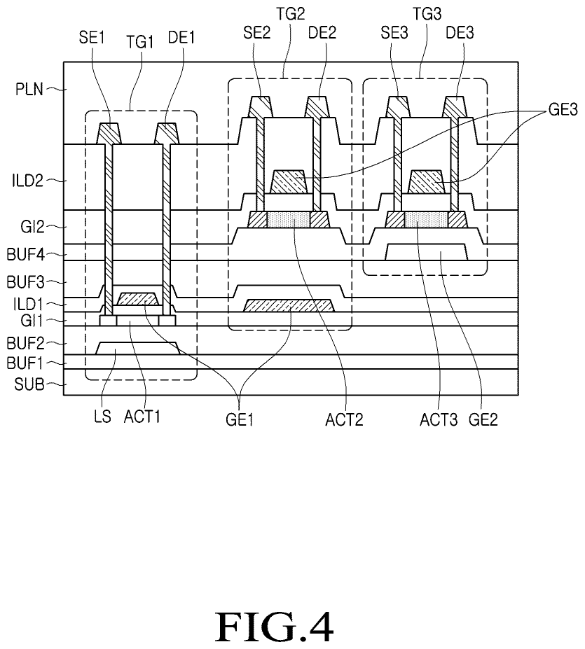

FIG. 4 is an example cross-sectional view of transistors included in a subpixel SP in the display device 100 according to embodiments of the present disclosure.

Referring to FIG. 4, in one or more example embodiments, the display device 100 may include a first buffer layer BUF1 disposed on a substrate SUB.

A light shield layer LS for shielding light may be disposed on the buffer layer BUF1.

A second buffer layer BUF2 may be disposed such that it covers the light shield layer LS.

A first active layer ACT1 included in a first transistor TG1 may be disposed on the second buffer layer BUF2.

The first transistor TG1 may be one of switching transistors implemented as a low-temperature polysilicon transistor among switching transistors included in the subpixel SP. For example, in the subpixel of FIG. 3, the second to fourth switching transistors (T2, T3, and T4) and the sixth and seventh switching transistors (T6 and T7) may be implemented as low-temperature polysilicon transistors.

A first gate insulating layer GI1 may be disposed on the first active layer ACT1.

At least one first gate electrode GE1 including a gate material may be disposed on the first gate insulating layer GI1. The gate material may be an opaque conductive material having low resistance, such as aluminum (Al), aluminum alloy (Al alloy), tungsten (W), copper (Cu), nickel (Ni), chromium (Cr), molybdenum (Mo), titanium (Ti), platinum (Pt), tantalum (Ta), and the like. In one or more aspects, the gate material may be formed as a multilayer structure in which at least one transparent conductive material, such as indium-tin oxide (ITO), indium-zinc oxide (IZO), and the like, and at least one opaque conductive material are stacked sequentially or alternately,

The at least one first gate electrode GE1 may serve as the gate electrode of the first transistor TG1 and serve as a lower gate electrode of a second transistor TG2 disposed at a location spaced apart from the first transistor TG1.

For example, the second transistor TG2 may be a switching transistor implemented as an oxide transistor in the subpixel. In the subpixel of FIG. 3, the first switching transistor T1 and the fifth switching transistor T5 may be implemented as oxide transistors.

In one or more embodiments, the second transistor TG2 may have a dual gate structure including upper and lower gate electrodes. In this implementation, the first gate electrode GE1 may serve as the lower gate electrode of the second transistor TG2.

A first interlayer insulating layer ILD1 may be disposed such that it covers the first gate electrode GE1.

A third buffer layer BUF3 may be disposed on the first interlayer insulating layer ILD1.

A second gate electrode GE2 including the gate material may be disposed on the third buffer layer BUF3.

The second gate electrode GE2 may be a lower gate electrode of a third transistor TG3 disposed at a location spaced apart from the second transistor TG2.

For example, the third transistor TG3 may be a driving transistor DRT implemented as an oxide transistor in the subpixel.

In one or more embodiments, the third transistor TG3 may have a dual gate structure including upper and lower gate electrodes. In this implementation, the second gate electrode GE2 may be the lower gate electrode of the second transistor TG3.

For example, the second transistor TG2 and the third transistor TG3 implemented as oxide transistors may include the lower gate electrode GE1 and the lower gate electrode GE2, respectively, disposed in different layers in the vertical direction.

A fourth buffer layer BUF4 may be disposed such that it covers the second gate electrode GE2 on the third buffer layer BUF3.

A second active layer ACT2 included in the second transistor TG2 and a third active layer ACT3 included in the third transistor TG3 may be disposed on the fourth buffer layer BUF4.

The second active layer ACT2 may be the active layer of the second transistor TG2 implemented as an oxide transistor, and the third active layer ACT3 may be the active layer of the third transistor TG3, which is a driving transistor, implemented as an oxide transistor.

A second gate insulating layer GI2 may be disposed such that it covers the second active layer ACT2 and the third active layer ACT3 Two or more third gate electrodes GE3 including the gate material may be disposed on the second gate insulating layer GI2.

Among the two or more third gate electrodes GE3, one third gate electrode GE3 may be the upper gate electrode of the second transistor TG2, and another third gate electrode GE3 may be the upper gate electrode of the third transistor TG3.

A second interlayer insulating layer ILD2 may be disposed such that it covers the two or more third gate electrodes GE3.

A plurality of source-drain electrode patterns may be disposed on the second interlayer insulating layer ILD2.

The source-drain electrode patterns may include any one of molybdenum (Mo), titanium (Ti), tantalum (Ta), tungsten (W), copper (Cu), chromium (Cr), aluminum (Al), and an alloy formed from a combination thereof.

One of the source-drain electrode patterns may be the first source electrode SE1 and the first drain electrode DE1 of the first transistor TG1. Another one of the source-drain electrode patterns may be the second source electrode SE2 and the second drain electrode DE2 of the second transistor TG2. Further another one of the source-drain electrode patterns may be the third source electrode SE3 and the third drain electrode DE3 of the third transistor TG3.

In one or more embodiments, portions of at least two of the source-drain electrode patterns may be electrically connected to the second active layer ACT2 of the second transistor TG2 and the third active layer ACT3 of the third transistor TG3, respectively, through contact holes of the second interlayer insulating layer ILD2 and the second gate insulating layer GI2.

In one or more embodiments, portions of the remaining at least one source-drain electrode pattern of the source-drain electrode patterns may be electrically connected to the first active layer ACT1 of the first transistor TG1 through contact holes of the second interlayer insulating layer ILD2, the second gate insulating layer GI2, the fourth buffer layer BUF4, the third buffer layer BUF3, the first interlayer insulating layer ILD1, and the first gate insulating layer GI1.

A planarization layer PLN may be disposed such that it covers the source-drain electrode patterns. The planarization layer PLN may include an organic insulating material such as an acrylic resin. In one or more aspects, the driving transistor DRT and one or more switching transistors (e.g., T1 and T5) included in the subpixel SP may have a dual gate structure including upper and lower gate electrodes to improve a current characteristic in a turn-on state and provide high reliability.

In this regard, while the display panel 110 is driven to display an image, a charge injection phenomenon may occur along an active layer ACT during a process where a switching transistor connected to the driving transistor DRT is turned on and off, and this may cause a leakage current to flow. Thereby, undesirable image artifacts such as flicker and the like may occur.

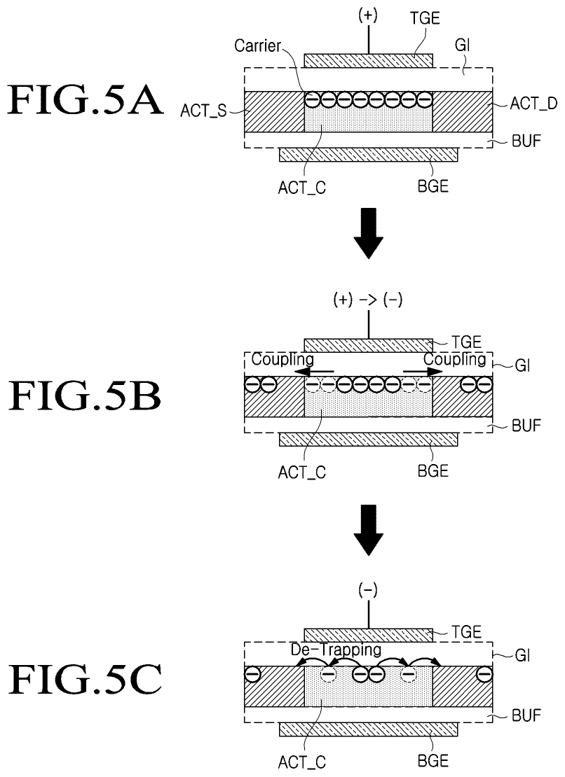

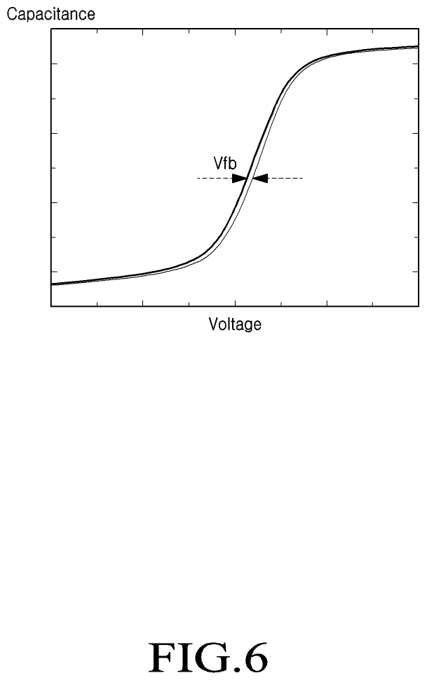

FIGS. 5A to 5C illustrate example states of carriers in a situation where a transistor operates according to one embodiment, and FIG. 6 illustrates an example C-V characteristic of a transistor according to frequencies according to one embodiment.

Referring to FIGS. 5A to 5C, in one or more embodiment, an active layer ACT of a transistor may include, on a substrate (not shown), conductive semiconductor patterns (ACT_S and ACT_D) to which a source electrode SE and a drain electrode DE with a channel layer ACT_C therebetween are electrically connected respectively. In one or more embodiments, an upper gate electrode TGE may overlap with the channel layer ACT_C with a gate insulating layer GI therebetween.

The channel layer ACT_C may be a region doped with various types of impurities and having a semiconductor surface. The channel layer ACT_C may include different semiconductor materials or different semiconductor material layers such as a bulk semiconductor material (e.g., silicon) of the substrate, silicon germanium (SiGe), or silicon carbide (SiC).

In the case of an N-type transistor, the conductive semiconductor patterns (ACT_S and ACT_D) electrically connected to the source electrode SE and the drain electrode DE may be regions doped with an N-type impurity. The conductive semiconductor patterns (ACT_S and ACT_D) may be formed by ion implantation or diffusion. For example, a rapid thermal annealing process may be used to activate the implanted impurities during the process of forming the conductive semiconductor patterns (ACT_S and ACT_D).

The gate insulating layer GI may include a dielectric material such as silicon oxide. in one or more embodiment, the gate insulating layer GI may include one or more other suitable dielectric materials for circuit performance and manufacturing integration. For example, the gate insulating layer GI may include a layer of a high-k dielectric material such as a metal oxide, a metal nitride, or a metal oxynitride. The high-k dielectric material layer may include a metal oxide, such as ZrO2, Al2O3, and HfO2, formed by any suitable method, such as metal organic chemical vapor deposition (MOCVD), physical vapor deposition (PVD), atomic layer deposition (ALD), or molecular beam epitaxy (MBE).

The upper gate electrode TGE may include a metal, such as aluminum, copper, tungsten, a metal silicide, a metal alloy, doped polysilicon, another suitable conductive material, or a combination thereof. The upper gate electrode TGE may include a plurality of conductive films designed such as a capping layer, a work function metal layer, a blocking layer, and a filling metal layer (e.g., aluminum or tungsten).

For example, when the N-type transistor is turned on by a gate voltage with a high level applied to the upper gate electrode TGE, carriers in the channel layer ACT_C can be trapped to form a channel (FIG. 5A).

In this state, when the gate voltage applied to the upper gate electrode TGE changes from the high level to a low level, a kick-back phenomenon may occur instantaneously due to the change in the gate voltage. That is, the conductive semiconductor patterns (ACT_S, ACT_D) may be temporarily coupled with the channel layer ACT_C, and this may cause an instantaneous change in potential (FIG. 5B).

After this kickback phenomenon, the carriers trapped in the channel layer ACT_C may be de-trapped, and a charge injection phenomenon may occur in which the carriers are injected into the conductive semiconductor patterns (ACT_S and ACT_D). Due to this charge injection phenomenon, a leakage current may flow in the driving transistor (FIG. 5C).

As discussed above, in a situation where the leakage current flows to the upper gate electrode TGE of the transistor, a change in luminance may occur, and in turn, some image artifacts such a flicker and the like may occur.

This phenomenon can occur not only in transistors with dual gate electrodes but also in transistors with single gate electrodes as upper gate electrodes.

In particular, when the display device 100 operates at a low driving frequency, this phenomenon may act as one cause that worsens the flicker phenomenon as a time delay of several seconds is caused due to a leakage current caused by charge injection.

In this case, as shown in FIG. 6, a C-V (capacitance-voltage) characteristic curve of the driving transistor may shift according to a driving frequency.

For example, the flicker characteristic of the transistor may be analyzed based on a deviation Vfb in voltages of the transistor having a same capacitance at different first and second driving frequencies.

To accurately measure a deviation Vfb in voltages according to driving frequencies, it is desirable to minimize the formation of an overlap capacitance by gate electrodes of the transistor.

To this end, for accurately analyzing the characteristics of one or more transistors, the display device 100 may include at least one test transistor in the non-display area NDA of the display panel 110. A detected operation characteristic of the at least one test transistor in the non-display area NDA is representative of the operation characteristic of a corresponding transistor in the display area DA. Thus, the detected operation characteristic of the at least one test transistor is a proxy for the operation characteristic of the corresponding transistor in the display area DA.

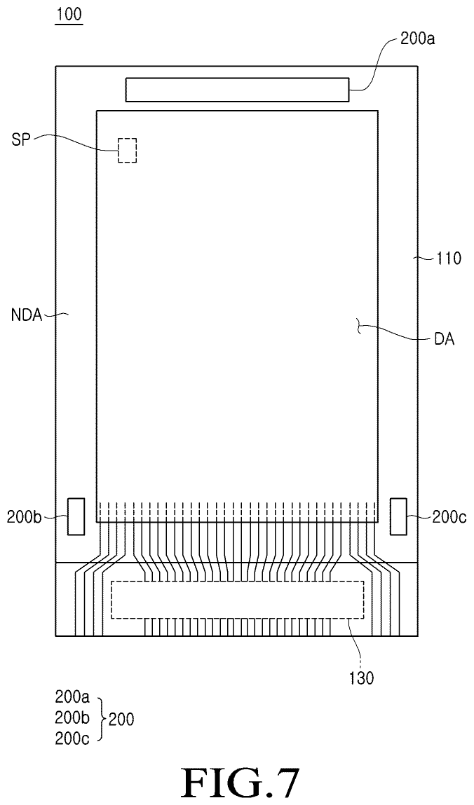

FIG. 7 is an example plan view of the display device 100 according to embodiments of the present disclosure.

Referring to FIG. 7, in one or more example embodiments, the display panel 110 included in the display device 100 may include the display area DA in which at least one subpixel SP is configured to emit light and the non-display area NDA in which an image is not displayed.

In one or more embodiments, the display device 100 may include a test area 200 in the non-display area NDA located outside of the display area DA to analyze a characteristic of one or more transistors located in the display area DA.

The test area 200 may include a plurality of test areas (200a, 200b, and/or 200c) to detect C-V characteristics of transistors having different structures.

For example, a first test transistor for detecting a C-V characteristic of a driving transistor DRT implemented as an oxide transistor may be disposed in a first test area 200a. The C-V characteristic of the first test transistor may be detected and represents the C-V characteristic of the driving transistor DRT, for example.

A second test transistor for detecting a C-V characteristic of an oxide switching transistor may be disposed in a second test area 200b. The C-V characteristic of the second test transistor may be detected and represents the C-V characteristic of the oxide switching transistor, for example. Lastly, a third test transistor for detecting a C-V characteristic of a silicon switching transistor may be disposed in a third test area 200c. The C-V characteristic of the third test transistor may be detected and represents the C-V characteristic of the silicon switching transistor, for example.

To detect the C-V characteristics of transistors located in the display area DA, a plurality of test transistors may be connected in parallel so that capacitances greater than a certain level can be accumulated.

For example, test transistors formed in each test area 200 may be connected in parallel so that a capacitance in a range of 5 pF to 20 pF can be accumulated in the parallel connected test transistors.

The first test area 200a may be disposed in a portion of the non-display area NDA farthest away from the data driving circuit 130 with respect to the display area DA. When the first test area 200a is disposed in the portion of the non-display area NDA farthest away from the data driving circuit 130, the first test area 200a may have a straight structure.

The second test area 200b and the third test area 200c may be disposed at corners of the non-display area NDA adjacent to the data driving circuit 130. When the second test area 200b and the third test area 200c are disposed at corners of the non-display area NDA, the second test area 200b and the third test area 200c may have a non-straight structure with at least one bent portion.

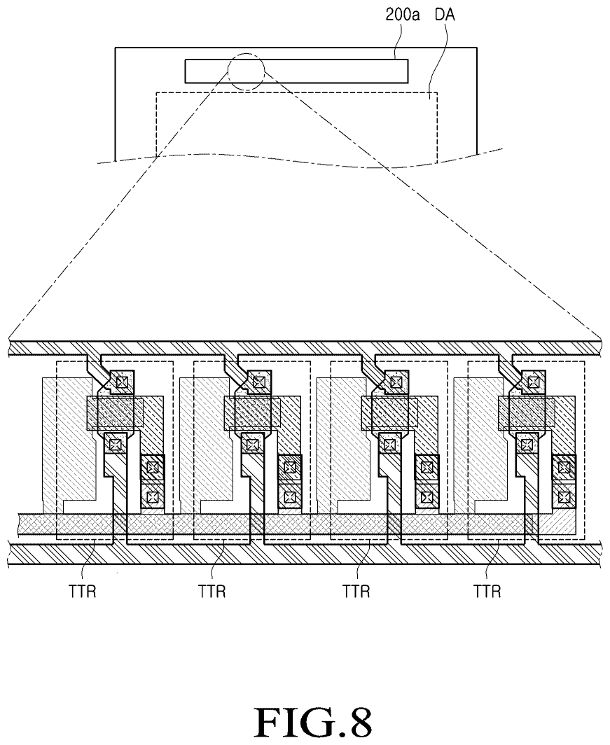

FIG. 8 illustrates an example arrangement structure of test transistors in a test area in the display device 100 according to embodiments of the present disclosure.

Referring to FIG. 8, in one or more example embodiments, the display device 100 may include a test area 200a in which a plurality of test transistors TTR are connected in parallel in a portion of the non-display area NDA, which is adjacent to an outer edge of the display area DA.

For example, a first test area 200a in which one or more test transistors TTR for detecting a C-V characteristic of a driving transistor DRT are disposed may be disposed at a location opposite to the data driving circuit 130 with respect to the display area DA.

A plurality of test transistors TTR for detecting a C-V characteristic of a driving transistor DRT may be disposed in parallel in the first test area 200a. For example, 300 or fewer test transistors TTR may be connected in parallel in the test area 200.

Since the test transistors TTR disposed in the first area 200a are located for detecting the C-V characteristic of the driving transistor DRT, the test transistors TTR are connected in parallel so that capacitances formed in the test transistors TTR can be accumulated according to one embodiment. For example, the plurality of test transistors TTR can be connected such that a capacitance in a range of 5 pF to 20 pF can be accumulated so that the C-V characteristic of the driving transistor DRT can be detected.

It should be noted that the parallel connection of the plurality of test transistors TTR may mean that the plurality of test transistors TTR are disposed such that the drain electrodes DE of the test transistors are connected to each other and the source electrodes SE of the test transistors are connected to each other.

According to this configuration, when the plurality of test transistors TTR are connected in parallel to each other, respective capacitances formed in the test transistors TTR may be added, and a capacitance obtained by the adding may be detected as the capacitance of the test transistors TTR.

To detect a flicker characteristic of a driving transistor DRT using the test transistors TTR, it may be needed to accurately detect an interface characteristic of a buffer layer through each lower gate electrode and accurately detect an interface characteristic of a gate insulating layer through each upper gate electrode.

To this end, it is desirable to minimize an overlap capacitance formed between the gate electrodes and one or more other metal electrodes (e.g., corresponding source and drain electrodes).

In one or more embodiments, the display device 10 can reduce such an overlap capacitance based on a structure where the lower gate electrodes of the test transistors TTR are disposed not to vertically overlap with corresponding source and drain electrodes (SE and DE). That is the lower gate electrodes of the test transistors TTR are non-overlapping with the source and drain electrodes.

Further, the display device 100 can reduce a resistance component of the test transistors TTR and accurately detect a C-V characteristic of a transistor based on a structure where the lower gate electrode of each test transistor TTR is electrically connected to a corresponding base metal layer.

It should be understood here that the structures of the test transistors TTR may be different depending on types of transistors for detecting C-V characteristics.

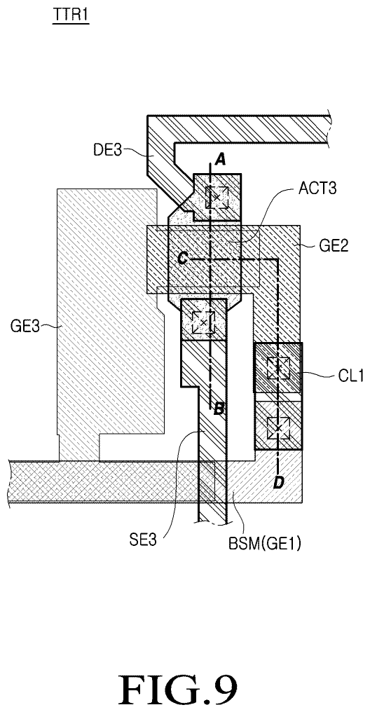

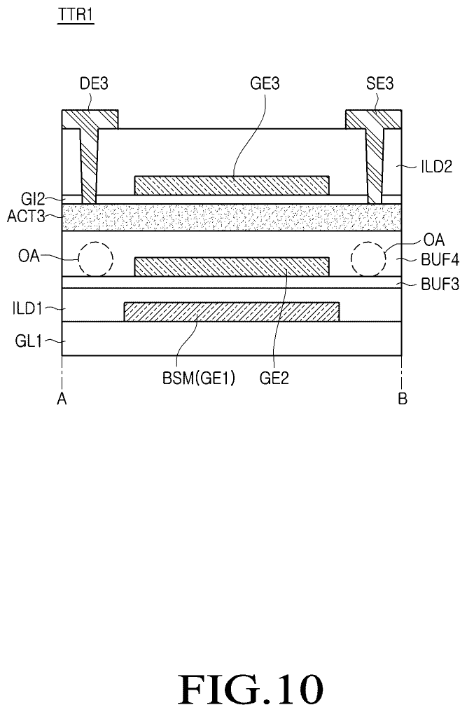

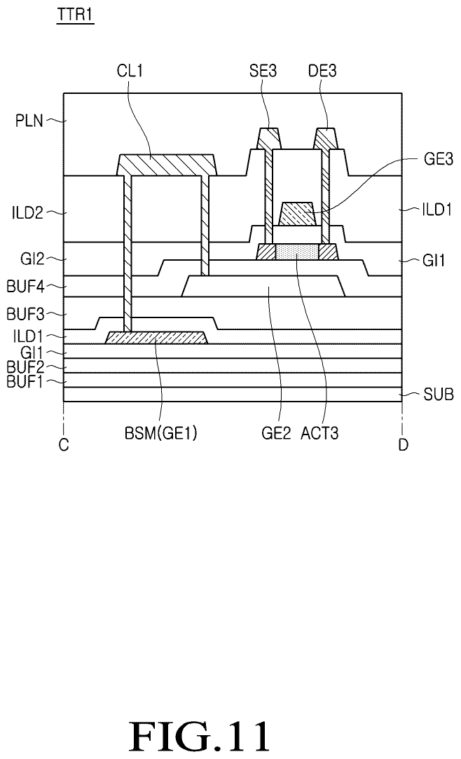

FIG. 9 is an example plan view of a first test transistor disposed in a test area for detecting a C-V characteristic of a driving transistor in the display device 100 according to embodiments of the present disclosure. FIG. 10 is an example cross-sectional view of the first test transistor taken along line A-B in FIG. 9 according to embodiments of the present disclosure. FIG. 11 is an example cross-sectional view of the first test transistor taken along line C-D in FIG. 9 according to embodiments of the present disclosure.

Referring to FIGS. 9 and 10, in one or more example embodiments, a first test transistor TTR1 disposed in a first test area 200a (e.g., the first test area 200a of FIGS. 7 and 8) included in the display device 100 may be disposed in a portion of the non-display area NDA by the same process as at least one driving transistor DRT disposed in the display area DA. Thus, the first test transistor TTR1 is disposed on a same layer as the at least one driving transistor DRT.

In one or more embodiments, the first test transistor TTR1 may include a base metal layer BSM disposed on the substrate SUB.

The base metal layer BSM may be disposed in the same layer as a first gate electrode GE1 using a first gate metal material for forming the first gate electrode GE1.

The base metal layer BSM may be electrically connected to a second gate electrode GE2 serving as a lower gate electrode of a driving transistor DRT to reduce a resistance of the second gate electrode GE2. The base metal layer BSM may apply a voltage less than or equal to a threshold to the second gate electrode GE2 to detect a C-V characteristic of the first test transistor TTR1.

A first interlayer insulating layer ILD1 may be disposed such that it covers the base metal layer BSM, and a third buffer layer BUF3 may be disposed on the first interlayer insulating layer ILD1. The second gate electrode GE2 may be disposed on the third buffer layer BUF3. The second gate electrode GE2 may serve as a lower gate electrode or bottom gate electrode of the first test transistor TTR1.

In these configurations, the second gate electrode GE2 is disposed such that it does not overlap with a third source electrode SE3 and a third drain electrode DE3 located over the second gate electrode GE2 in the vertical direction according to one embodiment.

For example, the second gate electrode GE2 may be located between overlap areas OA overlapping with the third source electrode SE3 and the third drain electrode DE3 in the vertical direction.

A fourth buffer layer BUF4 may be disposed on the second gate electrode GE2, and a third active layer ACT3 implemented as an oxide semiconductor may be disposed on the fourth buffer layer BUF4.

A second gate insulating layer GI2 and a third gate electrode GE3 are sequentially disposed on the third active layer ACT3. The third gate electrode GE3 may be referred to as an upper gate electrode or top gate electrode of the first test transistor TTR.

The third gate electrode GE3 may include the same material as the second gate electrode GE2.

A second interlayer insulating layer ILD2 may be disposed on the third gate electrode GE3.

A contact hole may be formed to expose a portion of the third active layer ACT3 by the etching of respective portions of the second interlayer insulating layer ILD2 and the second gate insulating layer GI2, and the third source electrode SE3 and the third drain electrode DE3 that contact the third active layer ACT3 may be formed through the contact hole.

In this configuration, even when the third source electrode SE3 and the third drain electrode DE3 are disposed on overlap areas OA in the vertical direction, since the second gate electrode GE2 is not disposed in the overlap areas OA, therefore, an overlap capacitance formed between at least one of the third source electrode SE3 and the third drain electrode DE3 and the second gate electrode GE2 can be minimized.

In one or more embodiments, one or more driving transistors DRT disposed in the display area DA may be disposed such that a second gate electrode GE2 overlaps with, or does not overlap with, at least one of a third source electrode SE3 and a third drain electrode DE3 in the vertical direction.

Referring to FIGS. 9 and 11, in one or more example embodiments, the second gate electrode GE2 of the first test transistor TTR1 disposed in the portion of the non-display area NDA of the display device 100 may be electrically connected to the base metal layer BSM under the second gate electrode GE2 through a first connection line CL1.

Through this configuration, a resistance component of the second gate electrode GE2 can be reduced, and a C-V characteristic of the first test transistor TTR1 can be detected more accurately.

The first connection line CL1 may be disposed in the same layer as the third source electrode SE3 and the third drain electrode DE3, and electrically interconnect the second gate electrode GE2 and the base metal layer BSM.

In one or more embodiments, the first connection line CL1 may be disposed at a location that does not overlap (e.g., non-overlapping) with the third source electrode SE3 and the third drain electrode DE3 in the vertical direction. Thereby, an overlap capacitance formed between the first connection line CL1 and at least one of the third source electrode SE3 and the third drain electrode DE3 can be minimized or at least reduced.

In one or more embodiments, driving transistors DRT disposed in the display area DA may not include a first connection line CL1, and therefore, a second gate electrode GE2 of each driving transistor DRT may not be electrically connected to a base metal layer BSM located under the second gate electrode GE2.

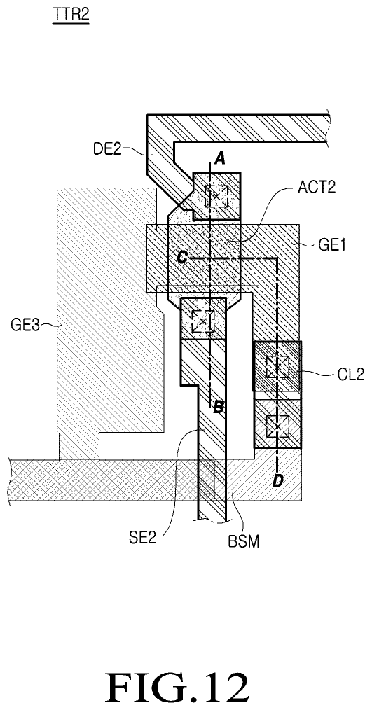

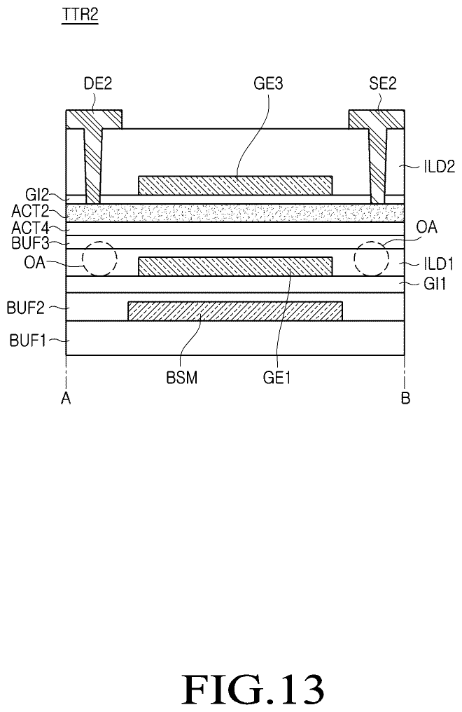

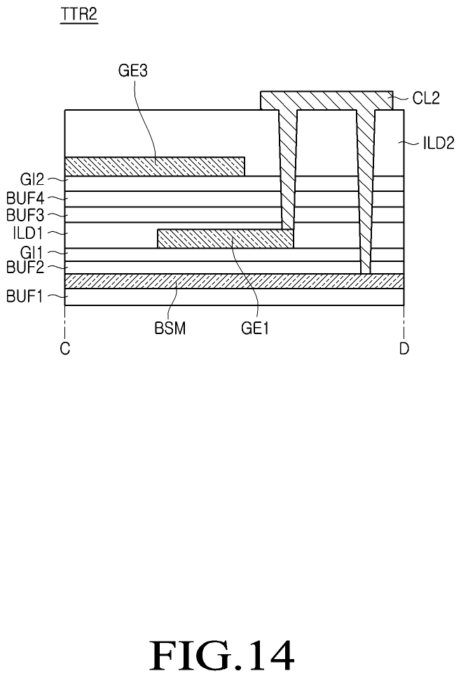

A C-V characteristic of the first test transistor TTR1 can be accurately detected by grounding the base metal layer BSM or applying a low voltage less than or equal to a reference value, FIG. 12 is an example plan view of a second test transistor disposed in a test area for detecting a C-V characteristic of an oxide switching transistor in the display device 100 according to embodiments of the present disclosure. FIG. 13 is an example cross-sectional view of the second test transistor taken along line A-B in FIG. 12 according to embodiments of the present disclosure. FIG. 14 is an example cross-sectional view of the second test transistor taken along line C-D in FIG. 12 according to embodiments of the present disclosure.

Referring to FIGS. 12 to 14, in one or more example embodiments, a second test transistor TTR2 disposed in a second test area 200b (e.g., the second test area 200b of FIG. 7) included in the display device 100 may be disposed in a portion of the non-display area NDA by the same process as at least one oxide switching transistor among switching transistors disposed in the display area DA. Thus, the second test transistor TTR2 is disposed on a same layer as the at least one oxide switching transistor.

In one or more embodiments, the second test transistor TTR2 may include a base metal layer BSM disposed on the substrate SUB.

The base metal layer BSM may be located under a first gate electrode GE1 and be a metal layer separated from the first gate electrode GE1.

The base metal layer BSM may be electrically connected to the first gate electrode GE1 serving as a lower gate electrode of an oxide switching transistor to reduce a resistance of the first gate electrode GE1. The base metal layer BSM may apply a voltage less than or equal to a threshold value to the first gate electrode GE1 to detect a C-V characteristic of the second test transistor TTR2 corresponding to the oxide switching transistor.

A second buffer layer BUF2 may be disposed such that it covers the base metal layer BSM, and a first gate insulating layer GI1 may be disposed on the second buffer layer BUF2.

The first gate electrode GE1 may be disposed on the first gate insulating layer GI1, and a first interlayer insulating layer ILD1 may be disposed such that the first interlayer insulating layer ILD1 covers the first gate electrode GE1.

The first gate electrode GE1 may serve as a lower gate electrode or bottom gate electrode of the second test transistor TTR2.

A third buffer layer BUF3 and a fourth buffer layer BUF4 may be sequentially disposed on the first interlayer insulating layer ILD1.

In these configurations, the first gate electrode GE1 is disposed such that it does not overlap (e.g., non-overlapping) with a second source electrode SE2 and a second drain electrode DE2 located over the first gate electrode GE1 in the vertical direction.

For example, the first gate electrode GE1 may be located between overlap areas OA overlapping with the second source electrode SE2 and the second drain electrode DE2 in the vertical direction.

A second active layer ACT2, a second gate insulating layer GI2, and a third gate electrode GE3 may be sequentially disposed on the fourth buffer layer BUF4. The third gate electrode GE3 may be referred to as an upper gate electrode or top gate electrode of the second test transistor TTR2.

The third gate electrode GE3 may include the same material as the first gate electrode GE1.

A second interlayer insulating layer ILD2 may be disposed on the third gate electrode GE3.

A contact hole may be formed to expose a portion of the second active layer ACT2 by the etching of respective portions of the second interlayer insulating layer ILD2 and the second gate insulating layer GI2, and the second source electrode SE2 and the second drain electrode DE2 that contact the second active layer ACT2 may be formed through the contact hole.

In this configuration, even when the second source electrode SE2 and the second drain electrode DE2 are disposed on overlap areas OA in the vertical direction, since the first gate electrode GE1 is not disposed in the overlap areas OA, therefore, an overlap capacitance formed between at least one of the second source electrode SE2 and the second drain electrode DE2 and the first gate electrode GE1 can be minimized.

In one or more embodiments, one or more oxide switching transistors disposed in the display area DA may be disposed such that a second gate electrode GE1 overlaps with, or does not overlap with, at least one of a second source electrode SE2 and a second drain electrode DE2 in the vertical direction.

In one or more embodiments, the first gate electrode GE1 of the second test transistor TTR2 disposed in the portion of the non-display area NDA of the display device 100 may be electrically connected to the base metal layer BSM under the first gate electrode GE1 through a second connection line CL2.

Through this configuration, a resistance component of the first gate electrode GE1 can be reduced, and a C-V characteristic of the second test transistor TTR2 can be detected more accurately.

The second connection line CL2 may be disposed in the same layer as the second source electrode SE2 and the second drain electrode DE2, and electrically interconnect the first gate electrode GE1 and the base metal layer BSM through a contact hole.

In one or more embodiments, the second connection line CL2 may be disposed at a location that does not overlap with the second source electrode SE2 and the second drain electrode DE2 in the vertical direction. Thereby, an overlap capacitance formed between the second connection line CL2 and at least one of the second source electrode SE2 and the second drain electrode DE2 can be minimized.

In one or more embodiments, oxide switching transistors disposed in the display area DA may not include a second connection line CL2, and therefore, a first gate electrode GE1 of each oxide switching transistor may not be electrically connected to a base metal layer BSM located under the first gate electrode GE.

A C-V characteristic of the second test transistor TTR2 can be accurately detected by grounding the base metal layer BSM or applying a low voltage less than or equal to a reference value,

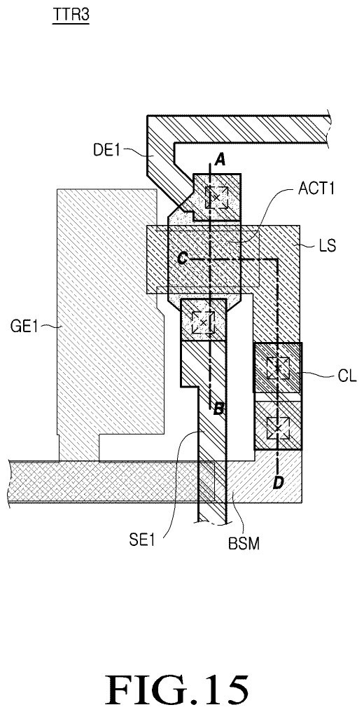

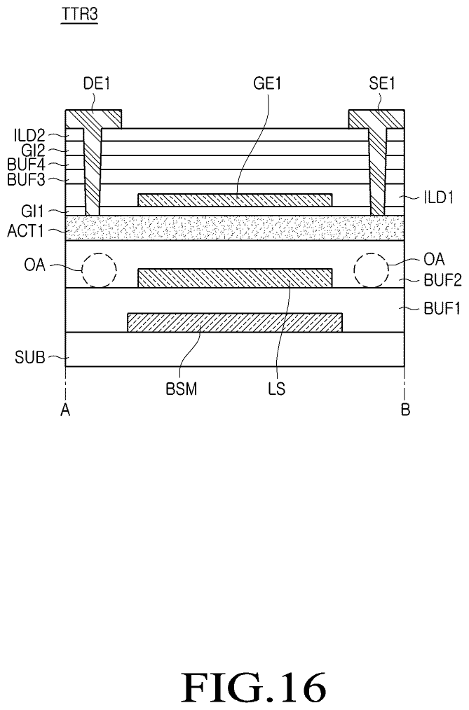

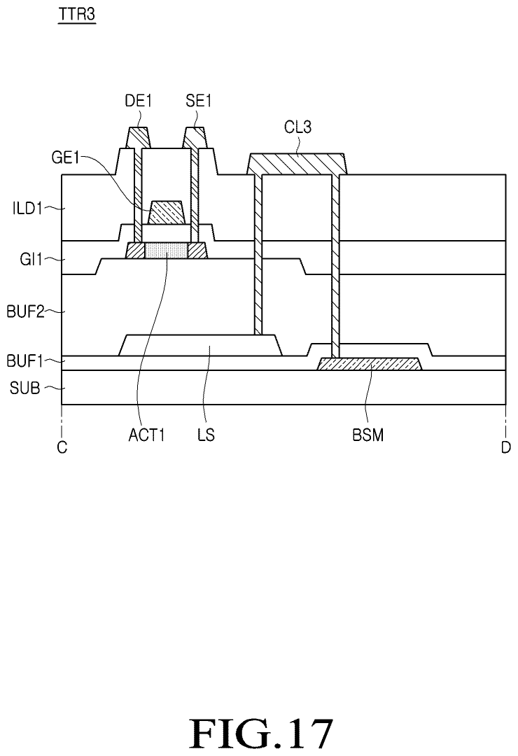

FIG. 15 is an example plan view of a third test transistor disposed in a test area for detecting a C-V characteristic of a polysilicon switching transistor in the display device 100 according to embodiments of the present disclosure. FIG. 16 is an example cross-sectional view of the third test transistor taken along line A-B in FIG. 15 according to embodiments of the present disclosure. FIG. 17 is an example cross-sectional view of the third test transistor taken along line C-D in FIG. 15 according to embodiments of the present disclosure.

Referring to FIGS. 15 to 17, in one or more example embodiments, a third test transistor TTR3 disposed in a third test area 200c (e.g., the third test area 200c of FIG. 7) included in the display device 100 may be disposed in a portion of the non-display area NDA by the same process as at least one polysilicon switching transistor among switching transistors disposed in the display area DA. Thus, the third test transistor TTR3 is disposed on a same layer as the at least one polysilicon switching transistor.

In one or more embodiments, the third test transistor TTR3 may include a base metal layer BSM disposed on the substrate SUB.

The base metal layer BSM may be a metal layer disposed under a light shield layer LS.

The base metal layer BSM may be electrically connected to the light shield layer LS of a polysilicon switching transistor to reduce a resistance of the light shield layer LS. The base metal layer BSM may apply a voltage less than or equal to a threshold value to the light shield layer LS to detect a C-V characteristic of the third test transistor TTR3 corresponding to the polysilicon switching transistor.

A first buffer layer BUF1 may be disposed such that it covers the base metal layer BSM, and the light shield layer LS may be disposed on the first buffer layer BUF1. The light shield layer LS is between the base metal layer BSM and a third active layer the first active layer ACT1.

A second buffer layer BUF2 may be disposed such that it covers the light shield layer LS, and the first active layer ACT1 may be disposed on the second buffer layer BUF2.

A first gate insulating layer GI1 may be disposed on the first active layer ACT1.

A first gate electrode GE1 may be disposed on the first gate insulating layer GI1, and a first interlayer insulating layer ILD1 may be disposed such that the first interlayer insulating layer ILD1 covers the first gate electrode GE1.

A third buffer layer BUF3 and a fourth buffer layer BUF4 may be sequentially disposed on the first interlayer insulating layer ILD1.

In these configurations, the light shield layer LS is disposed such that it does not overlap with a first source electrode SE1 and a first drain electrode DE1 located over the light shield layer LS in the vertical direction.

To this end, the light shield layer LS may be located between overlap areas OA overlapping with the first source electrode SE1 and the first drain electrode DE1 in the vertical direction.

A second gate insulating layer GI2 and a second interlayer insulating layer ILD2 may be disposed on the fourth buffer layer BUF4.

A contact hole may be formed to expose a portion of the first active layer ACT1 by the etching of respective portions of the second interlayer insulating layer ILD2, the second gate insulating layer GI2, the fourth buffer layer BUF4, the third buffer layer BUF3, the first interlayer insulating layer ILD1, and the first gate insulating layer GI1.

The first source electrode SE1 and the first drain electrode DE1 that contact the first active layer ACT1 through the contact hole may be formed.

In these configurations, even when the first source electrode SE1 and the first drain electrode DE1 are disposed on overlap areas OA in the vertical direction, since the light shield layer LS is not disposed in the overlap areas OA, therefore, an overlap capacitance formed between at least one of the first source electrode SE1 and the first drain electrode DE1 and the light shield layer LS can be minimized.

In one or more embodiments, one or more polysilicon switching transistors disposed in the display area DA may be disposed such that a light shield layer LS overlaps with, or does not overlap with, at least one of a first source electrode SE1 and a first drain electrode DE1 in the vertical direction.

In one or more embodiments, the light shield layer LS of the third test transistor TTR3 disposed in the portion of the non-display area NDA of the display device 100 may be electrically connected to the base metal layer BSM under the light shield layer LS through a third connection line CL3.

Through this configuration, a resistance component of the light shield layer LS can be reduced, and a C-V characteristic of the third test transistor TTR3 can be detected more accurately.

The third connection line CL3 may be disposed in the same layer as the first source electrode SE1 and the first drain electrode DE1, and electrically interconnect the light shield layer LS and the base metal layer BSM through a contact hole.

In one or more embodiments, the third connection line CL3 may be disposed at a location that does not overlap with the first source electrode SE1 and the first drain electrode DE1 in the vertical direction. Thereby, an overlap capacitance formed between the third connection line CL3 and at least one of the first source electrode SE1 and the first drain electrode DE1 can be minimized.

In one or more embodiments, polysilicon switching transistors disposed in the display area DA may not include a third connection line CL3, and therefore, a light shield layer LS of each polysilicon switching transistor may not be electrically connected to a base metal layer BSM located under the light shield layer LS.

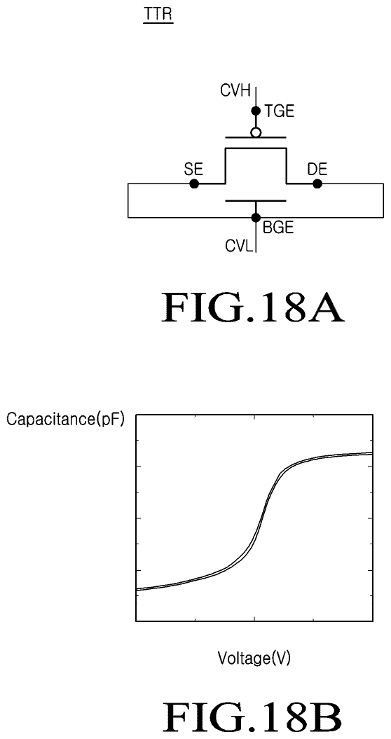

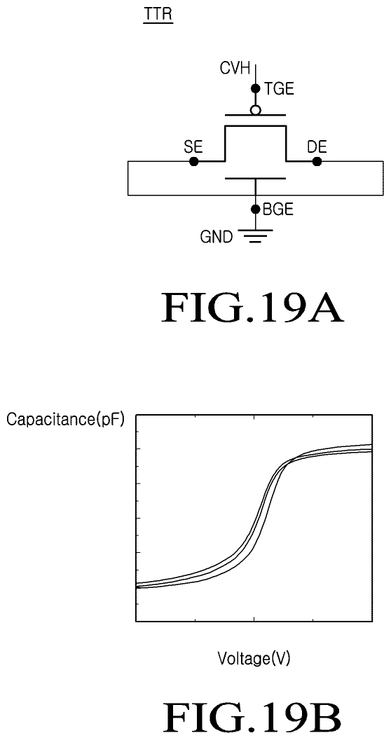

A C-V characteristic of the third test transistor TTR3 can be accurately detected by grounding the base metal layer BSM or applying a low voltage less than or equal to a reference value, FIG. 18A illustrates voltages applied to the test transistor TTR and FIG. 18B is a graph showing an example C-V characteristic when a low voltage that is greater than ground is applied to a lower gate electrode of a test transistor in the display device 100 according to embodiments of the present disclosure. FIG. 19A illustrates voltages applied to the test transistor TTR and FIG. 19B is a graph showing an example C-V characteristic when a lower gate electrode of a test transistor is grounded in the display device according to embodiments of the present disclosure.

Referring to FIGS. 18A and 18B, in one or more embodiments, the display device 100 can detect a C-V characteristics of a test transistor TTR by applying test voltages (CVH and CVL) to gate electrodes (TGE and BGE) of the test transistor TTR disposed in a test area 200.

For example, as shown in circuit FIG. 18A, a test pad of the source electrode SE and a test pad of the drain electrode DE of the test transistor TTR may be electrically connected. In this configuration, a first test voltage CVL may be applied to a lower gate electrode BGE, and a second test voltage CVH may be applied to an upper gate electrode TGE. (FIG. 18A)

For example, the first test voltage CVL applied to the lower gate electrode BGE may have a lower voltage than the second test voltage CVH applied to the upper gate electrode TGE.

In this state, a C-V characteristics of the test transistor TTR can be detected while varying the second test voltage CVH applied to the upper gate electrode TGE.

In this example, it can be seen that capacitance in the C-V characteristic of the test transistor TTR varies rapidly with respect to the second test voltage CVH of 0 V. Therefore, for respective cases where a low-frequency driving frequency is applied and a high-frequency driving frequency is applied, a flicker characteristic of the test transistor TTR can be analyzed by detecting a deviation of the second test voltage CVH at points where the capacitance varies rapidly. (FIG. 18B) Referring to FIG. 19, in one or more embodiments, the display device 100 can detect a C-V characteristics of a test transistor TTR by grounding a lower gate electrode BGE of a test transistor TTR disposed in a test area 200 and applying a test voltage CVH to an upper gate electrode TGE thereof.

For example, as shown in the circuit of FIG. 19A, a test pad of the source electrode SE and a test pad of the drain electrode DE of the test transistor TTR may be electrically connected. In this configuration, the lower gate electrode BGE may be grounded, and a test voltage CVH may be applied to the upper gate electrode TGE. (FIG. 19A)

In this state, a C-V characteristics of the test transistor TTR can be detected while varying the test voltage CVH applied to the upper gate electrode TGE.

In this example, it can be seen that capacitance in the C-V characteristic of the test transistor TTR varies rapidly with respect to the test voltage CVH of 0 V. Therefore, for respective cases where a low-frequency driving frequency is applied and a high-frequency driving frequency is applied, a flicker characteristic of the test transistor TTR can be analyzed by detecting a deviation of the test voltage CVH at points where the capacitance varies rapidly. (FIG. 19B)

As discussed above, as the display device 10 has a configuration where a lower gate electrode of a test transistors TTR is disposed not to vertically overlap with corresponding source and drain electrodes (SE and DE), the display device 100 can provide effects or advantages of reducing overlap capacitance and reducing an error in detecting the C-V characteristic of the transistor.

Further, as the display device 100 has a configuration where a lower gate electrode of a test transistor TTR is electrically connected to a base metal layer, the display device 100 can provide effects or advantages of reducing the resistance component of the test transistor TTR and accurately detecting the C-V characteristic of the test transistor TTR.

The example embodiments described herein will be briefly described as follows.

In one embodiment, display device comprising: a display panel comprising a display area in which subpixels are disposed to display an image and a non-display area outside of the display area in which the image is not displayed; and a driving circuit configured to drive the display panel, wherein the non-display area comprises test areas that include a plurality of test transistors, and a detected operation characteristic of the plurality of test transistors is representative of an operating characteristic of at least one of a plurality of transistors included in the subpixels.

In one embodiment, the test areas comprise: a first test area in the non-display area, the first test area including at least one first test transistor that corresponds to at least one oxide driving transistor among the plurality of transistors that are included in the subpixels; and a second test area in the non-display area, the second test area including at least one second test transistor that corresponds to at least one oxide switching transistor among the plurality of transistors included in the subpixels.

In one embodiment, wherein the at least one first test transistor comprises: a base metal layer on a substrate; a lower gate electrode overlapping the base metal layer; a first active layer overlapping the lower gate electrode; an upper gate electrode overlapping the first active layer; and a first drain electrode contacting a first portion of the first active layer and a first source electrode contacting a second portion of the first active layer, wherein the lower gate electrode is non-overlapping with the first drain electrode and the first source electrode.

In one embodiment, the base metal layer comprises a same material as a lower gate electrode of the at least one oxide driving transistor.

In one embodiment, the lower gate electrode comprises a same material as a lower gate electrode of the at least one oxide driving transistor, wherein the first active layer comprises a same material as an active layer of the at least one oxide driving transistor, wherein the upper gate electrode comprises a same material as an upper gate electrode of the at least one oxide driving transistor, and wherein the first source electrode comprises a same material as a source electrode of the at least one oxide driving transistor and the first drain electrode comprises a same material as a drain electrode of the at least one oxide driving transistor.

In one embodiment, the display device further comprises: a first connection line that electrically connects the lower gate electrode and the base metal layer.

In one embodiment, the first connection line comprises a same material as the first source electrode and the first drain electrode, and the first connection line electrically connects the lower gate electrode and the base metal layer through a contact hole.

In one embodiment, the base metal layer is grounded and the detected operation characteristic includes a capacitance-voltage characteristic that is detected through the upper gate electrode.

In one embodiment, the detected operation characteristic includes a capacitance-voltage characteristic that is detected through the upper gate electrode while the base metal layer is applied with a first test voltage and the upper gate electrode is applied with a second test voltage that is greater than the first test voltage.

In one embodiment, the at least one second test transistor comprises: a base metal layer on a substrate; a lower gate electrode overlapping the base metal layer; a second active layer overlapping the lower gate electrode; an upper gate electrode overlapping the second active layer; and a second drain electrode contacting a first portion of the second active layer and a second source electrode contacting a second portion of the second active layer, wherein the lower gate electrode is non-overlapping with the second drain electrode and the second source electrode.

In one embodiment, the lower gate electrode comprises a same material as a lower gate electrode of the at least one oxide switching transistor, wherein the second active layer comprises a same material as an active layer of the at least one oxide switching transistor, wherein the upper gate electrode comprises a same material as an upper gate electrode of the at least one oxide switching transistor, and wherein the second source electrode comprises a same material as a source electrode of the at least one oxide switching transistor and the second drain electrode comprises a same material as a drain electrode of the at least one oxide switching transistor.

In one embodiment, the display device further comprises: a second connection line that electrically connects the lower gate electrode and the base metal layer.

In one embodiment, the second connection line is in a same layer as the second drain electrode and the second source electrode, and the second connection line electrically connects the lower gate electrode and the base metal layer through a contact hole.

In one embodiment, the base metal layer is grounded and the detected operation characteristic includes a capacitance-voltage characteristic that is detected through the upper gate electrode.

In one embodiment, the detected operation characteristic includes a capacitance-voltage characteristic that is detected through the upper gate electrode while the base metal layer is applied with a first test voltage and the lower gate electrode is applied with a second test voltage that is greater than the first test voltage.

In one embodiment, an upper gate electrode of the at least one oxide driving transistor and an upper gate electrode of the at least one oxide switching transistor are in a same layer, and a lower gate electrode of the at least one oxide driving transistor and a lower gate electrode of the at least one oxide switching transistor are in different layers.

In one embodiment, the test areas further comprise: a third test area in the non-display area, the third test area including at least one third test transistor that corresponds to at least one polysilicon switching transistor among the plurality of transistors included in the subpixels.

In one embodiment, the at least one third test transistor comprises: a base metal layer on a substrate; a light shield layer overlapping the base metal layer; a third active layer overlapping the light shield layer such that the light shield layer is between the base metal layer and the third active layer; a gate electrode overlapping the third active layer; and a third drain electrode contacting a first portion of the third active layer and a third source electrode contacting a second portion of the third active layer, and wherein the light shield layer is non-overlapping with the third drain electrode and the third source electrode.

In one embodiment, the light shield layer comprises a same material as a light shield layer of the at least one polysilicon switching transistor, wherein the third active layer comprises a same material as an active layer of the at least one polysilicon switching transistor, wherein the gate electrode comprises a same material as a gate electrode of the at least one polysilicon switching transistor, and wherein the third source electrode comprises a same material as a source electrode of the at least one polysilicon switching transistor and the third drain electrode comprises a same material as a drain electrode of the at least one polysilicon switching transistor.

In one embodiment, the display device further comprises: a third connection line that electrically connects the light shield layer and the base metal layer.

In one embodiment, the third connection line is in a same layer as the third drain electrode and the third source electrode, and the third connection line electrically connects the light shield layer and the base metal layer through a contact hole.

In one embodiment, the plurality of test transistors are connected in parallel.

In one embodiment, the plurality of test transistors are connected in parallel such that a capacitance accumulated in the plurality of test transistors is in a range of 5 pF to 20 pF.

In one embodiment, a display panel comprises: a display area including a plurality of subpixels; and a non-display area outside of the display area in which an image is not displayed, the non-display area comprising test areas including a plurality of test transistors, wherein an operation characteristic of the plurality of test transistors is detected that is representative of an operation characteristic of a plurality of transistors included in the plurality of subpixels.

In one embodiment, the test areas comprise: a first test area in the non-display area, the first test area including at least one first transistor that corresponds to at least one oxide driving transistor among the plurality of transistors that are included in the plurality of subpixels; and a second test area in the non-display area, the second test area including at least one second transistor that corresponds to at least one oxide switching transistor among the plurality of transistors included in the plurality of subpixels.

In one embodiment, a display panel comprises: a substrate including a display area and a non-display area that is around the display area, the non-display area including a test area; a transistor in the display area of the substrate; a light emitting element in the display area, the transistor connected to the light emitting element; a plurality of test transistors in the test area of the non-display area, at least one test transistor of the plurality of test transistors on a same layer as the transistor, wherein the at least one test transistor includes: a base metal layer in the test area; a lower gate electrode overlapping the base metal layer in the test area; an active layer overlapping the lower gate electrode in the test area; an upper gate electrode overlapping the active layer in the test area; and a drain electrode contacting a first portion of the active layer in the test area and a source electrode contacting a second portion of the active layer in the test area, and wherein the lower gate electrode is non-overlapping with the drain electrode and the source electrode in the test area.

In one embodiment, the transistor is an oxide driving transistor and the lower gate electrode of the at least one test transistor comprises a same material as a lower gate electrode of the oxide driving transistor, wherein the active layer of the at least one test transistor comprises a same material as an active layer of the oxide driving transistor, wherein the upper gate electrode of the at least one test transistor comprises a same material as an upper gate electrode of the oxide driving transistor, and wherein the source electrode of the at least one test transistor comprises a same material as a source electrode of the oxide driving transistor and the drain electrode of the at least one test transistor comprises a same material as a drain electrode of the oxide driving transistor.

In one embodiment, the display panel further comprises: a connection line electrically connecting the lower gate electrode and the base metal layer.

In one embodiment, the connection line comprises a same material as the source electrode and the drain electrode of the at least one test transistor, and the connection line electrically interconnects the lower gate electrode and the base metal layer of the at least one test transistor through a contact hole.

In one embodiment, the plurality of test transistors are connected in parallel and a detected operation characteristic of the plurality of test transistors is representative of an operating characteristic of the transistor.

In one embodiment, the base metal layer of the at least one test transistor is grounded and the detected operation characteristic includes a capacitance-voltage characteristic that is detected through the upper gate electrode of the at least one test transistor.

In one embodiment, the detected operation characteristic includes a capacitance-voltage characteristic that is detected through the upper gate electrode of the at least one test transistor while the base metal layer of the at least one test transistor is applied with a first test voltage and the upper gate electrode of each of the at least one test transistor is applied with a second test voltage that is greater than the first test voltage.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device comprising:
a display panel comprising a display area in which subpixels are disposed to display an image and a non-display area outside of the display area in which the image is not displayed; and
a driving circuit configured to drive the display panel,
wherein the non-display area comprises test areas that include a plurality of test transistors, and a detected operation characteristic of the plurality of test transistors is representative of an operating characteristic of at least one of a plurality of transistors included in the subpixels.

2. The display device of claim 1, wherein the test areas comprise:
a first test area in the non-display area, the first test area including at least one first test transistor that corresponds to at least one oxide driving transistor among the plurality of transistors that are included in the subpixels; and
a second test area in the non-display area, the second test area including at least one second test transistor that corresponds to at least one oxide switching transistor among the plurality of transistors that are included in the subpixels.

3. The display device of claim 2, wherein the at least one first test transistor comprises:
a base metal layer on a substrate;
a lower gate electrode overlapping the base metal layer;
a first active layer overlapping the lower gate electrode;
an upper gate electrode overlapping the first active layer; and
a first drain electrode contacting a first portion of the first active layer and a first source electrode contacting a second portion of the first active layer,
wherein the lower gate electrode is non-overlapping with the first drain electrode and the first source electrode.

4. The display device of claim 3, wherein the base metal layer comprises a same material as a lower gate electrode of the at least one oxide switching transistor.

5. The display device of claim 3, wherein the lower gate electrode comprises a same material as a lower gate electrode of the at least one oxide driving transistor,
wherein the first active layer comprises a same material as an active layer of the at least one oxide driving transistor,
wherein the upper gate electrode comprises a same material as an upper gate electrode of the at least one oxide driving transistor, and
wherein the first source electrode comprises a same material as a source electrode of the at least one oxide driving transistor and the first drain electrode comprises a same material as a drain electrode of the at least one oxide driving transistor.

6. The display device of claim 3, further comprising:
a first connection line that electrically connects the lower gate electrode and the base metal layer.

7. The display device of claim 6, wherein the first connection line comprises a same material as the first source electrode and the first drain electrode, and the first connection line electrically connects the lower gate electrode and the base metal layer through a contact hole.

8. The display device of claim 6, wherein the base metal layer is grounded and the detected operation characteristic includes a capacitance-voltage characteristic that is detected through the upper gate electrode.

9. The display device of claim 6, wherein the detected operation characteristic includes a capacitance-voltage characteristic that is detected through the upper gate electrode while the base metal layer is applied with a first test voltage and the upper gate electrode is applied with a second test voltage that is greater than the first test voltage.

10. The display device of claim 2, wherein the at least one second test transistor comprises:
a base metal layer on a substrate;
a lower gate electrode overlapping the base metal layer;
a second active layer overlapping the lower gate electrode;
an upper gate electrode overlapping the second active layer; and
a second drain electrode contacting a first portion of the second active layer and a second source electrode contacting a second portion of the second active layer,
wherein the lower gate electrode is non-overlapping with the second drain electrode and the second source electrode.

11. The display device of claim 10, wherein the lower gate electrode comprises a same material as a lower gate electrode of the at least one oxide switching transistor,
wherein the second active layer comprises a same material as an active layer of the at least one oxide switching transistor,
wherein the upper gate electrode comprises a same material as an upper gate electrode of the at least one oxide switching transistor, and
wherein the second source electrode comprises a same material as a source electrode of the at least one oxide switching transistor and the second drain electrode comprises a same material as a drain electrode of the at least one oxide switching transistor.

12. The display device of claim 10, further comprising:
a second connection line that electrically connects the lower gate electrode and the base metal layer.

13. The display device of claim 12, wherein the second connection line is in a same layer as the second drain electrode and the second source electrode, and the second connection line electrically connects the lower gate electrode and the base metal layer through a contact hole.

14. The display device of claim 12, wherein the base metal layer is grounded and the detected operation characteristic includes a capacitance-voltage characteristic that is detected through the upper gate electrode.

15. The display device of claim 12, wherein the detected operation characteristic includes a capacitance-voltage characteristic that is detected through the upper gate electrode while the base metal layer is applied with a first test voltage and the lower gate electrode is applied with a second test voltage that is greater than the first test voltage.

16. The display device of claim 2, wherein an upper gate electrode of the at least one oxide driving transistor and an upper gate electrode of the at least one oxide switching transistor are in a same layer, and a lower gate electrode of the at least one oxide driving transistor and a lower gate electrode of the at least one oxide switching transistor are in different layers.

17. The display device of claim 2, wherein the test areas further comprise:
a third test area in the non-display area, the third test area including at least one third test transistor that corresponds to at least one polysilicon switching transistor among the plurality of transistors included in the subpixels.

18. The display device of claim 17, wherein the at least one third test transistor comprises:
a base metal layer on a substrate;
a light shield layer overlapping the base metal layer;
a third active layer overlapping the light shield layer such that the light shield layer is between the base metal layer and the third active layer;
a gate electrode overlapping the third active layer; and
a third drain electrode contacting a first portion of the third active layer and a third source electrode contacting a second portion of the third active layer,
wherein the light shield layer is non-overlapping with the third drain electrode and the third source electrode.

19. The display device of claim 18, wherein the light shield layer comprises a same material as a light shield layer of the at least one polysilicon switching transistor,
wherein the third active layer comprises a same material as an active layer of the at least one polysilicon switching transistor,
wherein the gate electrode comprises a same material as a gate electrode of the at least one polysilicon switching transistor, and
wherein the third source electrode comprises a same material as a source electrode of the at least one polysilicon switching transistor and the third drain electrode comprises a same material as a drain electrode of the at least one polysilicon switching transistor.

20. The display device of claim 18, further comprising:
a third connection line that electrically connects the light shield layer and the base metal layer.

21. The display device of claim 20, wherein the third connection line is in a same layer as the third drain electrode and the third source electrode, and the third connection line electrically connects the light shield layer and the base metal layer through a contact hole.

22. The display device of claim 1, wherein the plurality of test transistors are connected in parallel.

23. The display device of claim 22, the plurality of test transistors are connected in parallel such that a capacitance accumulated in the plurality of test transistors is in a range of 5 pF to 20 pF.

24. A display panel comprising:
a display area including a plurality of subpixels; and
a non-display area outside of the display area in which an image is not displayed, the non-display area comprising test areas including a plurality of test transistors,
wherein an operation characteristic of the plurality of test transistors is detected that is representative of an operation characteristic of a plurality of transistors included in the plurality of subpixels.

25. The display panel of claim 24, wherein the test areas comprise:
a first test area in the non-display area, the first test area including at least one first transistor that corresponds to at least one oxide driving transistor among the plurality of transistors that are included in the plurality of subpixels; and
a second test area in the non-display area, the second test area including at least one second transistor that corresponds to at least one oxide switching transistor among the plurality of transistors included in the plurality of subpixels.

26. A display panel comprising:
a substrate including a display area and a non-display area that is around the display area, the non-display area including a test area;
a transistor in the display area of the substrate;
a light emitting element in the display area, the transistor connected to the light emitting element;
a plurality of test transistors in the test area of the non-display area, at least one test transistor of the plurality of test transistors on a same layer as the transistor,
wherein the at least one test transistor includes:
a base metal layer in the test area;
a lower gate electrode overlapping the base metal layer in the test area;
an active layer overlapping the lower gate electrode in the test area;
an upper gate electrode overlapping the active layer in the test area; and
a drain electrode contacting a first portion of the active layer in the test area and a source electrode contacting a second portion of the active layer in the test area, and
wherein the lower gate electrode is non-overlapping with the drain electrode and the source electrode in the test area.
